(19) United States
(12) Patent Application Publication
(10) Pub. No.: US 2008/0042129 A1
(43) Pub. Date: Feb. 21, 2008

(54) Organic Thin Film Transistor and Its Fabrication Method

(76) Inventors: Masatoshi Nakagawa, Nara-shi (JP); Hiroyuki Hanato, Nara-shi (JP); Toshihiro Tamura, Shiki-gun (JP)

Correspondence Address: EDWARDS ANGELL PALMER & DODGE LLP, P.O. BOX 55874, BOSTON, MA, 02205, US

(21) Appl. No.: 11/794,044

(22) PCT Filed: Dec. 21, 2005
(86) PCT No.: PCT/JP05/23514

§ 371 Date: Jun. 21, 2007

(30) Foreign Application Priority Data
Dec. 22, 2004 (JP) 2004-371789
Nov. 30, 2005 (JP) 2005-346654

(51) Int. Cl. H01L 51/10; H01L 51/40

(52) U.S. Cl. 257/40; 438/99; 257/E51.006; 257/E21.051

(57) ABSTRACT

An organic TFT comprising an organic thin film, a gate electrode formed on one surface of the organic thin film through a gate insulating film, source/drain electrodes formed on both sides of the gate electrode and on one surface of the organic thin film or on the other surface, and a film of an organic silane compound positioned between the organic thin film and the gate insulating film and/or between the organic thin film and the source/drain electrodes.

### TECHNICAL FIELD

The invention relates to an organic thin film transistor and its fabrication method. More particularly, the invention relates to an organic thin film transistor comprising a film of an organic silane compound and its fabrication method.

### BACKGROUND ART

In recent years, IC technologies using transistors based on organic semiconductors have been proposed. Main advantageous points of the above-mentioned technologies are simplicity of fabrication methods and compatibility with flexible substrates. These advantages are expected to be employed in low-cost IC technologies suitable for applications such as smart cards, electronic tags, and displays.

Today, as a film formation method to be employed at the time of fabricating a thin film transistor (TFT) using an organic semiconductor have been known a vacuum evaporation method and a coating method. These film formation methods make it possible to fabricate large scale devices with suppressed cost and to lower the process temperature required for the film formation to a relatively low level. Therefore, in the case of a TFT using an organic semiconductor (hereinafter, referred to as organic TFT), it is advantageous that materials usable for a substrate are less limited.

Japanese Unexamined Patent Publication No. 2003-258265 Patent Document 1) discloses an example of the organic TFT. The structure of the organic TFT described in this publication is shown in FIG. 5. FIG. 5 shows a TFT comprising a gate electrode 2, a gate insulating film 3, source/drain electrodes (5, 7), and a semiconductor layer (organic thin film) 6 formed on a substrate 1. This TFT is obtained by forming the gate electrode 2 on a part of the substrate 1; covering the gate electrode 2 and the substrate 1 with the gate insulating film 3; forming the source/drain electrodes (5, 7) on the gate insulating film 3 while sandwiching a region corresponding to the gate electrode 2; and covering the source/drain electrodes (5, 7) and the gate insulating film 3 with the semiconductor layer 6.

Examples of a material to be used for the semiconductor layer may be, as a material for a p-type semiconductor layer, a material selected from pentacene, tetracene, thiophene, phthalocyanine, their derivatives having substituents at their terminals as well as a polymer of polythiophene, polyphenylene, poly(phenylene vinylene), polyfluorene, and their derivative polymers having substituent groups at their terminals or side chains, and also as a material for an n-type semiconductor layer, a material selected from perylenetetracarboxylic acid dianhydride, napthalenetetracarboxylic acid dianhydride, fluorated phthalocyanine, and their derivatives having substituent groups at their terminals.

In general, the operation of the organic TFT is supposed as follows.

In the case voltage is applied to the gate electrode, the gate voltage causes bend of the band in the semiconductor layer on the interface side of the gate insulating film through the Fermi level change of the gate electrode. This bend of the band causes injection of a large number of positive charges, which are carriers, from the source/drain electrodes to form a region with a high surface charge density in the semiconductor layer on the gate insulating film interface side, that is, to form an accumulation layer of the carrier.

On the other hand, a depletion layer in which electric charge is eliminated is formed in the semiconductor layer on the gate insulating film interface side by reverse bias application to the gate electrode.

The organic TFT is operated by altering the electric current value flowing between the source electrode and the drain electrode by conductance control of the channel by gate voltage in such a manner.

Herein, although transfer of the carriers in the semiconductor layer is suppressed among grains, carriers are quickly transmitted while hopping between neighboring molecules in the insides of the grains due to the crystallinity, that is, periodic structure formation.

However, in the case of actual organic TFT fabrication/evaluation, the semiconductor layer is often formed by using an inorganic oxide such as SiO₂ as the gate insulating film and vapor-depositing an organic semiconductor material such as pentacene on the gate insulating film.

A material such as pentacene is strongly affected by the inorganic oxide composing the gate insulating film and prevented from stacking, which is a particular property of an organic material, so that there occurs a problem that the crystallinity of the semiconductor layer in the vicinity of the gate insulating film interface, that is, an accumulation layer of the carrier decrease.

Further, the surface energy of the gate insulating film containing the inorganic oxide is high and accordingly, the diffusion of molecules on the substrate is suppressed during the thin film growth process. Therefore, many adsorption sites are formed and as a result, only a film comprising grains with small grain sizes and having inferior crystallinity can be formed.

Decrease of the crystallinity of the semiconductor layer is a factor considerably affecting the device characteristics.

There is a report (IEEE Electron Device Lett., 18, 606, 1997: Non-Patent Document 1) that a semiconductor layer with a large grain size is produced by treating a gate insulating film with octadecyltrichlorosilane (OTS) for suppressing the decrease of the crystallinity and thereby adjusting the surface energy of the gate insulating film.

Further, in general, in the interface wherein different materials of source/drain electrodes and an organic thin film are brought into direct contact with one another, an energy barrier is generated. Therefore, gold, which is a material with a relatively low energy barrier in relation to the organic thin film, is often used for an electrode material composing the source/drain electrodes.

However, when an actual organic TFT is fabricated, if an inorganic oxide such as SiO₂ is used as a material for the gate insulating film, peeling of electrodes due to insufficient adhesion between the insulating film and the gold is caused. Therefore, a film made of Ti, Cr or the like is generally used as an under coating for gold in order to ensure adhesion between the both.

In this case, the film thickness of the under coating is generally about 5 to 10 nm. In the above-mentioned mechanism of the organic TFT, considering that the region of the organic thin film on which the carrier accumulation layer is to be formed is 10 and several nm or less from the insulating film interface, the energy barrier of the organic thin film with the under coating is actually dominant.

Herein, the following two are proposed as means for moderating the energy barrier in the interface of the source/drain electrodes and the organic thin film.

One proposal is use of an organic material (PEDOT/PSS) having conductivity as the electrode material (Applied Physics, 70, 12, 1452, 2001: Non-Patent Document 2). Devices are fabricated actually and confirmed to be operable, however these devices are found to have a disadvantageous point that they have high resistance values as those in the case of using metals as an electrode material.

To solve the above-mentioned problem, there is another proposal, that is, a method for improving properties by using an organic monomolecular film of mercaptopropyltriethoxysilane (MPTS) for the under coating and thereby adjusting the film thickness of the under coating to be 2 nm or thinner and effectively setting gold, which is used for electrodes, and the organic thin film close to the carrier accumulation layer (2004, IEEE International Solid-State Circuits Conference 715-718, Non-Patent Document 3). However, even in this method, the energy barrier cannot be moderated completely and further use of gold as the electrode material is disadvantageous in terms of the cost from a viewpoint of practical application.

Patent Document 1: Japanese Unexamined Patent Publication No. 2003-258265

Non-Patent Document 1: IEEE Electron Device Lett., 18, 606, 1997

Non-Patent Document 2: Applied Physics, 70, 12, 1452, 2001

Non-Patent Document 3: 2004, IEEE International Solid-state Circuits Conference 715-718

### DISCLOSURE OF THE INVENTION

### Problems to be Solved by the Invention

Since an organic TFT comprises a semiconductor layer formed directly on a gate insulating film, it has been implied to a certain extent that the uniformity of the semiconductor layer on the gate insulating film interface side becomes a factor considerably affecting the mobility. However, a proper material for the semiconductor layer and the degree of uniformity of the semiconductor layer formed using the material were not reported.

Further, the example described in the above-mentioned report describes no more than the suppression of the effects of the insulating film and thus does not refer to control of the crystallinity and the electric characteristics in the insulating film interface.

Further, since the surface uniformity of the semiconductor layer formed on the gate insulating film by a method such as vapor-deposition, or coating and successive firing is not well taken into consideration, there is a problem that the carrier mobility characteristic which the semiconductor layer intrinsically has is not sufficiently exhibited.

Further, in the organic TFT, a carrier mobility barrier is generated in the interface of two kinds of materials, that is, a metal electrode material and an organic semiconductor thin film material, having a direct contact with each other. It has also been implied to a certain extent that this barrier may possibly become a factor considerably affecting the device properties. However, the example described in the above-mentioned report describes no more than the suppression of the effects of the insulating film and thus does not refer to decrease of the energy barrier in the source/drain electrodes interface and control of the electric characteristics.

### Means for Solving the Problems

Accordingly, the present invention provides an organic TFT comprising an organic thin film, a gate electrode formed on one surface of the organic thin film through a gate insulating film, source/drain electrodes formed on both sides of the gate electrode and on one surface of the organic thin film or on the other surface, and a film of an organic silane compound positioned between the organic thin film and the gate insulating film and/or between the organic thin film and the source/drain electrodes.

Further, the present invention provides a fabrication method of the above-mentioned organic TFT comprising a step of forming a film of an organic silane compound between the organic thin film and the gate insulating film and/or between the organic thin film and the source/drain electrodes.

### EFFECTS OF THE INVENTION

An organic TFT of the invention comprises a film of an organic silane compound (an anchor film) between a gate insulating film and an organic thin film and carriers can be transported through both of the anchor film and the organic thin film, so that the carrier transportation efficiency is improved and high device properties can be obtained.

Further, crystal growth of the organic thin film can be controlled by optimizing the π electron conjugated system molecules in the main skeleton part of the anchor film. Therefore, since it is made possible to form an organic thin film with a high grain size, the crystallinity of the organic thin film can be improved.

Further, with respect to the TFT of the present invention, without being affected by the formation method of the organic thin film, the crystallinity of the organic thin film can be controlled by the interaction of the π electron conjugated system molecules in the main skeleton part of the anchor film and the organic thin film. That is, unlike a conventional organic TFT, the grain size of the organic thin film is not changed by the effect of the interaction with a substrate. Therefore, the invention can provide the organic thin film with constantly stable properties and also the organic TFT with stable properties.

Further, since the organic TFT of the invention comprises the film (a buffer film) of an organic silane compound between the source/drain electrodes and the organic thin film, the energy barrier between the electrodes and the organic thin film can be lowered and as a result, carrier transportation in the interface of different type solids can be carried out efficiently. Accordingly, the operation voltage is lowered and the carrier transportation property is improved in the organic TFT of the invention.

### BRIEF DESCRIPTION OF THE DRAWINGS

FIG. 1 is a schematic structural drawing of an organic TFT of the invention.

FIG. 2 is a magnified view of a gate insulating film, an anchor film, and an organic thin film part of the organic TFT of FIG. 1.

FIG. 3 is a schematic structural drawing of an organic TFT of the invention.

FIG. 4 is a schematic structural drawing of another organic TFT of the invention.

FIG. 5 is a schematic structural drawing of a conventional organic thin film transistor.

### EXPLANATION OF THE SYMBOLS

1 substrate
2 gate electrode
3 gate insulating film
4 anchorfilm
5, 7 source/drain electrodes
6 organic thin film (semiconductor layer)
10 arrow showing carrier transportation direction
11 arrow showing carrier transportation direction transversely crossing anchor film/organic thin film interface
41 buffer film

### BEST MODES FOR CARRYING OUT THE INVENTION

(Operation Principle)

One of the characteristics of the organic TFT of the invention is that the organic TFT comprises a film of an organic silane compound between an organic thin film and a gate insulating film and/or between the organic thin film and source/drain electrodes. Hereinafter, the function and the operation principle will be described separately for a film of an organic silane compound between the organic thin film and the gate insulating film and a film of an organic silane compound between the organic thin film and source/drain electrodes. For convenience, the former film of an organic silane compound is called as an anchor film and the latter film of an organic silane compound is called as a buffer film.

(a) Anchor Film

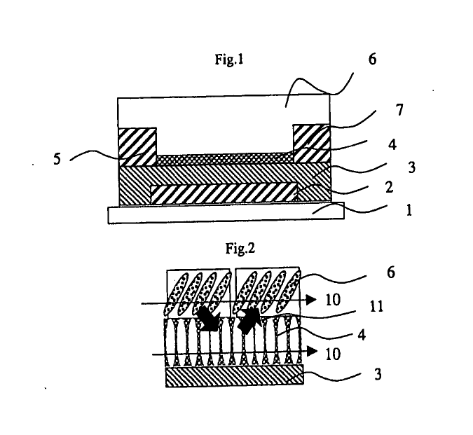

The organic TFT of the invention will be explained in accordance with FIGS. 1 and 2.

The organic TFT of FIG. 1 shows a bottom gate and a bottom contact type structure. As show in FIG. 1, the organic TFT of the invention is characterized in that an organic thin film 6 is formed on a gate insulating film 3 through an anchor film 4. In FIG. 1, 1 denotes a substrate; 2 denotes a gate electrode; 3 denotes a gate insulating film; and 5 and 7 denote source/drain electrodes. FIG. 2 shows a magnified drawing of the gate insulating film/anchor film/organic thin film part of FIG. 1. FIG. 1 shows an example in which the source/drain electrodes are formed on one surface side using the lower face of the organic thin film as the surface.

The structure of the organic TFT is not limited to the structure shown in FIG. 1 if the structure has the gate insulating film/anchor film/organic thin film structure in this order. Examples of other allowable structures are
(1) a structure in which the organic thin film and source/drain electrodes are formed on a substrate in this order and the anchor film, the gate insulating film, and the gate electrode are formed on the organic thin film between the source/drain electrodes in this order (an example of formation of the source/drain electrodes on one surface side which is an upper face of the organic thin film):
(2) a structure in which the gate electrode, the gate insulating film, the anchor film, the organic thin film, and the source/drain electrodes are formed in this order on a substrate (an example of formation of the source/drain electrodes on the other surface side which is an upper face of the organic thin film in the case the lower face of the organic thin film is set as one surface): and

(3) a structure in which source/drain electrodes are formed on a substrate and the organic thin film, the anchor film, and the gate insulating film are formed in this order so as to cover the source/drain electrodes and the gate electrode is formed on the gate insulating film (an example of formation of the source/drain electrodes on the other surface side which is a lower face of the organic thin film in the case the upper face of the organic thin film is set as one surface).

Herein, the most important point in these structures is formation of the anchor film, which is a monomolecular film (a thin film with a thickness equivalent to the size of one molecule) having a carrier transportation function, using an organic silane compound between the gate insulating film and the organic thin film. The anchor film has functions of controlling the crystallinity of the organic thin film and improving the device properties (e.g., carrier mobility, on/off ratio, and the like) of the organic thin film. The former function is a function provided in the case the gate insulating film, the anchor film, and the organic thin film are formed in this order. The latter function is a function provided as long as the anchor film is formed.

The function of controlling the crystallinity of the organic thin film is provided by controlling the surface energy of the gate insulating film with the anchor film. In other words, interposition of the anchor film makes it possible to form the organic thin film with a large grain size and improved crystallinity. More practically, the anchor film may be a film having chemical bonds with the gate insulating film owing to an Si—O—Si network derived from the chemically adsorbing group at the terminal of the organic silane compound and further may be a film having a periodic structure and formed on the gate insulating film owing to the interaction of the π electron conjugated system molecules, that is, the intermolecular power, on the above-mentioned network and is thus firmly fixed on the gate insulating film. As a result, even on the anchor film surface on the side where the organic thin film is to be formed, the crystallinity of the organic thin film to be formed on the anchor film can be improved due to the interaction of the π electron conjugated system molecules in the main skeleton part forming the organic silane monomolecular film.

The function of improving the device properties of the organic thin film is exhibited since the anchor film itself has the carrier transportation function. That is, in the organic TFT, the inventors have noted the fact that a region where the carriers are actually accumulated is a region to ten and several nm from the gate insulating film. That is, the inventors have noticed that if the carrier mobility in this region is improved, the device properties of the entire organic TFT can be improved. Therefore, the inventors have found that in addition to the improvement of the crystallinity of the organic thin film by the anchor film, the carrier mobility of the region where the carriers are actually transported can be improved if the anchor film itself has the carrier transportation function.

This carrier transportation function is derived from the formation of the anchor film using an organic silane compound containing π electron conjugated system molecules.

Further, since the π electron conjugated system molecules of the anchor film themselves have the carrier transportation function, the carrier mobility barrier in the interface of the organic thin film and the anchor film is relatively low. Therefore, carrier transportation via the interface as shown by the arrow 11 in FIG. 2 is also possible. Accordingly, transportation of the carrier across the interface can be utilized even in the part where the carrier transportation was conventionally difficult just as current transfer is difficult among grains.

Further, the anchor film is adjustable in the crystallinity in the vicinity of the interface of the organic thin film. Particularly, the anchor film is preferable to have higher crystallinity than that of the organic thin film. This is because the carrier mobility can be improved more and more electric current can flow by improving the crystallinity of the anchor film itself while taking into consideration that the region where the carriers can be transported is ten and several nm.

Further, since the anchor film can form the Si—O—Si network derived from the organic silane compound on the gate insulating film side, the organic group derived from the organic silane compound can be arranged more regularly on the gate insulating film than a film having no network. As a result, it is made possible to form the anchor film with high crystallinity.

The inventors confirmed diffraction peaks of several degrees attributed to the crystallinity by evaluating the height of the crystallinity of the anchor film by x-ray diffraction and electron diffraction. Further, the inventors suppose that the anchor film with high crystallinity is produced from an organic silane compound having π electron conjugated system molecules in the main skeleton and based on the bonds with the insulating film and the interaction of the π electron conjugated system molecules due to the Si—O—Si network.

The anchor film is formed so as to be a monomolecular film. The film thickness differs in accordance with the type of the organic silane compound. Practically, it is preferably 0.5 nm to 3 nm and more preferably 1 nm to 2.5 nm. Herein, it is not preferable that the thickness is thinner than 0.5 nm, since it is difficult to form an anchor film with high crystallinity. Further, in consideration of the structure of the compound for forming the organic thin film, it is also preferable that the π electron conjugated system molecules forming the main skeleton part of the organic silane compound to be used for the anchor film also have almost the same structure. Accordingly, it is not preferable that the film thickness is thicker than 3 nm, since the above-mentioned effects are not exhibited remarkably, and the transportation of carriers between the anchor film and the organic thin film is suppressed and the crystallinity of the anchor film itself is deteriorated. Also, in the case that the film thickness is thicker than 3 nm, the solubility of the organic silane compound for forming the anchor film is lowered, therefore a soluble substituent group, e.g., an alkyl group, has to be introduced into the terminal or side chains to avoid the decrease of solubility.

If a film with high crystallinity is used for the anchor film, the crystallinity of the organic thin film may not be so high as that of the anchor film. That is, if the anchor film with high crystallinity is formed, even if the organic thin film with low crystallinity is used, the carrier mobility in the region where the carriers are transported can be improved due to the existence of the anchor film and accordingly, it can be expected that the device properties of the organic TFT are improved. Therefore, the selectivity of raw materials for the organic thin film is improved and even relatively economical materials and fabrication methods can be selected, resulting in considerable industrial advantages. In addition, improvement of the crystallinity of the anchor film is effective to improve the crystallinity of the organic thin film to be formed thereon.

(b) Buffer Film

First, the carrier mobility barrier in the interface will be briefly described.

When two different type materials are directly brought into contact with each other, a carrier mobility barrier is generated in their interface. Although the above-mentioned carrier mobility barrier is always generated in the interface where different materials have a contact with each other, such as an organic thin film/organic thin film interface, a metal/organic thin film interface, and the like, the carrier mobility barrier value is particularly high in the metal/organic thin film interface. The carrier mobility barrier is a significant factor of preventing the carrier transportation in a device and particularly, the carrier mobility barrier in the metal/organic thin film interface considerably affects the intensity of the electric current flowing in a device and accordingly affects the device properties. The degree of the carrier mobility barrier depends on the energy level difference between the Fermi level of the metal and the orbit to be used for transportation of the charge contained in the organic thin film. Herein, in the case the carrier is a hole (an electron), the orbit to be used for transportation of the charge contained in the organic thin film is HOMO (LUMO).

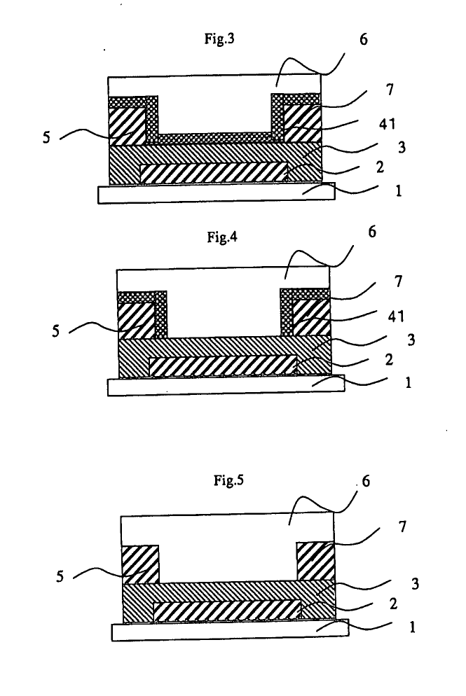

Based on the above-mentioned understandings, the organic TFT of the invention will be described along with FIG. 3.

FIG. 3 is a schematic structural drawing of an example of the organic TFT of the invention. The organic TFT of FIG. 3 has a bottom gate and a bottom contact type structure. As shown in FIG. 3, the organic TFT of the invention has a characteristic that the source/drain electrodes (5, 7) and the organic thin film 6 are formed while interposing a buffer film 41 between them.

The most advantageous point in this configuration is formation of a buffer film of an organic silane compound having a carrier transportation function between metal electrodes as a source electrode, a drain electrode, or both electrodes and an organic thin film. This buffer film has a function of improving the carrier transportation between different kinds of solids, that is, the metal electrode and the organic thin film. As described above, between different type solids, the carrier mobility barrier is generated corresponding to the gap between the Fermi level and the organic thin film level and this barrier is an issue relevant to the device operation.

To deal with the issue, the inventors have found that the carrier mobility barrier can be lowered by narrowing the gap between different type solids. Practically, the inventors have found that insertion of a buffer film having an intermediate value of the above-mentioned gap of different type solids as the molecular orbit usable for charge transportation between the metal electrode and the organic thin film can provide the organic TFT having an improved carrier transportation function between different type solids.

Further, if the carrier transportation between the metal/organic thin film is made more efficient in the organic TFT of the invention, the configuration is not limited to that shown in FIG. 3. That is, it is sufficient as long as the buffer layer is contained between the source/drain electrodes and the organic thin film, and the buffer film may entirely cover the source/drain electrodes as shown in FIG. 4.

Structures other than the structure described above may include, for example;

(1) a structure in which the organic thin film, the buffer film, and the source/drain electrodes are formed on a substrate in this order and the gate insulating film and the gate electrode are formed on the organic thin film between the source/drain electrodes in this order (an example of formation of the source/drain electrodes on one surface side which is an upper face of the organic thin film):

(2) a structure in which the gate electrode, the gate insulating film, the organic thin film, the buffer film, and the source/drain electrodes are formed in this order on a substrate (an example of formation of the source/drain electrodes on the other surface side which is an upper face of the organic thin film in the case the lower face of the organic thin film is set as one surface): and

(3) a structure in which the source/drain electrodes are formed on a substrate and the buffer film, the organic thin film, and the gate insulating film are formed in this order so as to cover the source/drain electrodes and the gate electrode is formed on the gate insulating film (an example of formation of the source/drain electrodes on the other surface side which is a lower face of the organic thin film in the case the upper face of the organic thin film is set as one surface).

(Configuration of the Organic TFT)

(a) Gate, Source/Drain Electrodes

A material for gate, source/drain electrodes is not particularly limited and all materials conventionally known in this field may be used. Practical materials may include metals such as gold, platinum, silver, copper, and aluminum; high melting point metals such as titanium, tantalum, and tungsten; silicides and polycides with high melting point metals; p-type or n-type highly doped silicon; conductive metal oxides such as ITO, NESA; and conductive polymers such as PEDOT. In the case the buffer film is formed, the material for the source/drain electrodes is preferably a metal material on whose surface an oxide film can be formed among these materials.

The film thickness is not particularly limited and may be properly adjusted to be the film thickness conventional in a common transistor (for example, 30 nm to 60 nm).

A formation method of these electrodes may be selected properly in accordance with the electrode material. Examples of the method may be vapor-deposition, sputtering, and coating.

(b) Gate Insulating Film

The gate insulating film is not particularly limited and all films conventionally known in this field may be used. Practical examples are insulating films such as a silicon oxide film (a thermal oxidation film, a low temperature oxidation film: an LTO film, a high temperature oxidation film: an HTO film); a silicon nitride film, an SOG film, a PSG film, a BSG film, and a BPSG film; PZT, PLZT, ferroelectrics or anti-ferroelectrics film; and low dielectric films such as an SiOF type film, an SiOC type film, and a CF type film, as well as an HSQ (hydrogen silsesquioxane) type film (inorganic), an MSQ (methyl silsesquioxane) type film, a PAE (polyarylene ether) type film, and a BCB type film formed by coating, and also porous type or CF type films or porous films.

The film thickness is not particularly limited and may be properly adjusted to be the film thickness conventional in a common transistor (for example, 100 nm to 500 nm).

A formation method of the gate insulating film may be selected properly in accordance with the type of the gate insulating film. Examples of the method may be vapor-deposition, sputtering, and coating.

(c) Film of Organic Silane Compound

A material for the film (anchor film and/or buffer film) of the organic silane compound is not particularly limited if it is an organic silane compound having the carrier transportation function after film formation. Practical examples of the organic silane compound are as follows.

A compound defined by the following formula (1) can be used as the organic silane compound.
R¹—SiZ¹Z²Z³ (1)

In the formula, Z¹ to Z³ may be same or different and independently denote preferably a halogen atom or an alkoxy atom having 1 to 5 carbon atoms. Examples of the halogen atom are fluorine atom, chlorine atom, bromine atom, and iodine atom and preferably chlorine atom. Examples of the alkoxy group are methoxy group, ethoxy group, propoxy group (including structural isomers), butoxy group (including structural isomers), and pentoxy group (including structural isomers).

R¹ is preferably an organic group containing π electron conjugated system molecules derived from a π electron conjugated system compound. The organic group is preferable to contain at least one group (unit) with which the conductivity can be controlled. For example, it may include groups selected from the groups derived from monocyclic aromatic compounds, condensed aromatic compounds, monocyclic heterocyclic compounds, and condensed heterocyclic compounds.

Examples of the monocyclic aromatic compounds are benzene, toluene, xylene, mesitylene, cumene and the like. Examples of the condensed aromatic compounds are naphthalene, anthracene, naphthacene, pentacene, hexacene, heptacene, octacene, nonacene, azulene, fluorene, pyrene, acenaphthene, perylene, anthraquinone and the like. Examples of the monocyclic heterocyclic compounds are furan, thiophene, pyridine, pyrimidine and the like. Examples of the condensed heterocyclic compounds are indole, quinoline, acridine, benzofuran and the like.

First, as the monocyclic aromatic compounds and monocyclic heterocyclic compounds, compounds consisting of units derived from benzene and/or thiophene are preferable. The compounds are preferable to be composed by bonding 2 to 8 units. In the case the units are bonded, it is more preferable that 2 to 6 units are bonded in terms of the yield, economy, and mass production.

Although a plurality of these units may be bonded in a branched state, however may be bonded preferably in a straight chain state. Each of the compounds may consist of same units bonded one another, or all different units bonded one another, or a plurality of kinds of units bonded orderly or randomly. With respect to the bonding positions, in the case the constituent molecule of a unit is thiophene, the positions may be 2,5-, 3,4-, 2,3-, or 2,4- and preferably 2,5-. In the case of benzene, the positions may be 1,4-, 1,2-, and 1,3- and preferably 1,4-.

Examples of a non-condensed aromatic compound may be benzene compounds defined by the following formula (2): 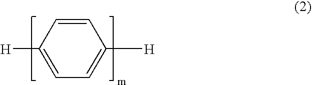
wherein, m denotes an integer of 1 to 8 and preferably an integer of 1 to 6. The phenylene group may have a substituent group such as an alkyl group, an aryl group, a halogen atom or the like.

Further, examples of a non-condensed aromatic heterocyclic compound may be thiophene compounds defined by the following formula (3): 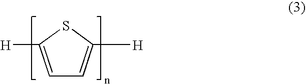
wherein, n denotes an integer of 1 to 8 and preferably an integer of 1 to 6. The thiophenediyl group may have a substituent group such as an alkyl group, an aryl group, a halogen atom or the like.

More practically, examples of the compounds consisting of two or more monocyclic aromatic compounds and/or monocyclic heterocyclic compounds bonded one another are groups derived from biphenyl, bithiophenyl, terphenyl (compound defined by the formula 1), terthienyl (compound defined by the formula 2), quaterphenyl, quaterthiophene, quinquephenyl, quinquethiophene, hexyphenyl, hexythiophene, thienyl-oligophenylene (refer to compound defined by the formula 3), phenyl-oligooligothienylene (refer to compound defined by the formula 4), block co-oligomer (refer to compound defined by the formula 5 or 6), bi(dithiophenylvinyl)phenyl (refer to compound defined by the formula 7) 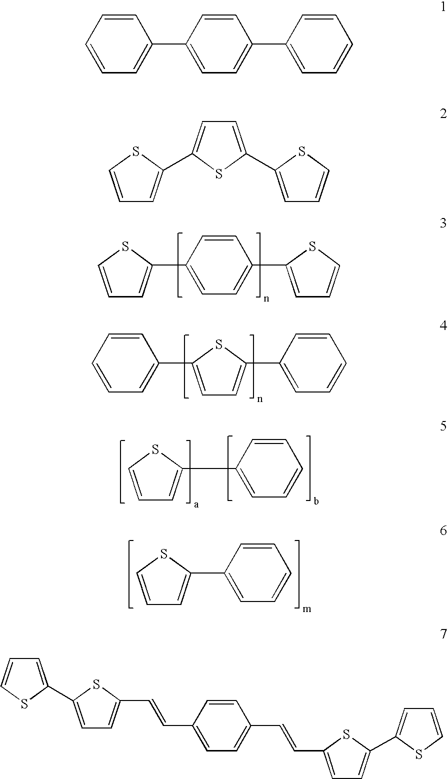
wherein, n denotes an integer of 1 to 6; m denotes an integer of 1 to 3; and a+b is 2 to 6.

Further, examples of the condensed aromatic compounds may include compounds (n denotes 0 to 4) selected from compounds defined by the following formulas 8 to 10.

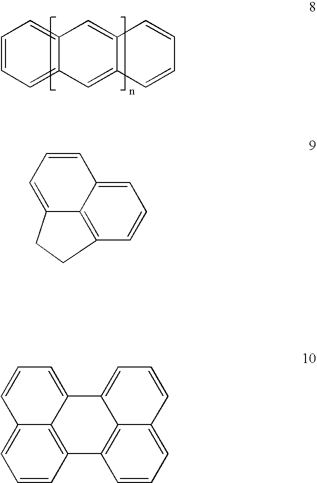

The formula 8 defines a compound containing an acene skeleton; the formula 9 defines a compound containing an acenaphthene skeleton; and the formula 10 defines a compound containing a perylene skeleton.

The number of benzene rings composing the compound containing the acene skeleton and defined by the formula 8 is preferably 2 to 8. In consideration of the number of the steps of the synthesis and the yield of a product, compounds containing 2 to 6 benzene rings such as naphthalene, anthracene, tetracene, pentacene, and hexacene are particularly preferable. In this connection, although the formula 8 shows the typical compound in which benzene rings are condensation-bonded linearly, the formula 8 also includes a compound obtained by non-linear condensation bonding, for example, phenanthrene, chrysene, picene, pentaphene, hexaphene, heptaphene, benzoanthracene, dibenzophenanthrene, anthranaphthacene and the like.

Further, examples of the condensed heterocyclic compounds are selected from compounds defined by the following formulas 11 to 16.

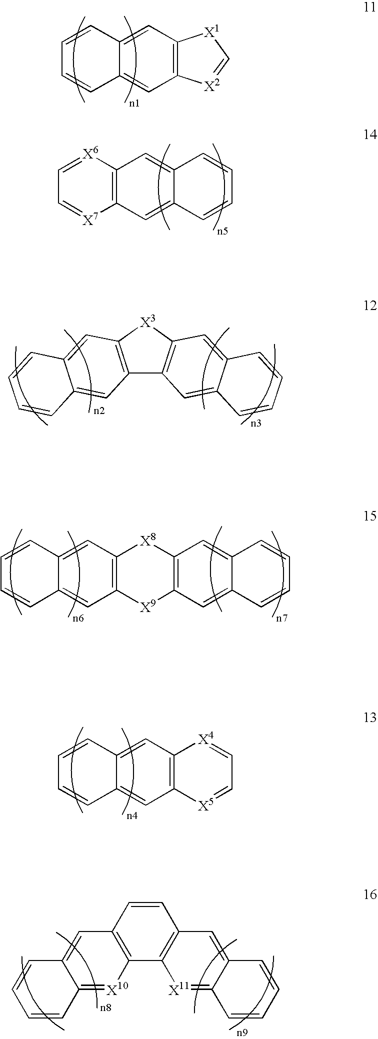

In the formula 11, X¹ denotes carbon atom, nitrogen atom, oxygen atom, or sulfur atom; and X² denotes carbon atom or nitrogen atom (excluding the case X¹ and X² simultaneously denote a carbon atom); and n1 denotes an integer of 0 to 4.

In the formula 12, X³ denotes nitrogen atom, oxygen atom, or sulfur atom; n2 and n3 independently denote an integer satisfying 0≦n2+n3≦−2.

In the formula 13, X⁴ and X⁵ independently denote carbon atom or nitrogen atom (excluding the case X⁴ and Xs simultaneously denote a carbon atom); and n4 denotes an integer of 0 to 4.

In the formula 14, X⁶ and X⁷ independently denote carbon atom or nitrogen atom (excluding the case X⁶ and X⁷ simultaneously denote carbon atom); and n5 denotes an integer of 0 to 4.

In the formula 15, X⁸ and X⁹ independently denote carbon atom, nitrogen atom, oxygen atom, or sulfur atom (excluding the case X⁸ and X⁹ simultaneously denote carbon atom); and n6 and n7 independently denote an integer satisfying 0≦n6+n7≦2.

In the formula 16, X¹⁰ and X¹¹ independently denote carbon atom or nitrogen atom (excluding the case X¹⁰ and X¹¹ simultaneously denote carbon atom); and n8 and n9 independently denote an integer satisfying 0≦n8+n9≦2.

A preferable organic group R¹ is a group derived from a compound consisting of two or more of monocyclic aromatic compounds and/or monocyclic heterocyclic compounds bonded one another or compounds containing the acene skeleton.

Particularly preferable examples of the organic group R¹ are

(1) monovalent groups containing π electron conjugated system molecules which are selected from molecules consisting of 2 to 6 repeated benzene, molecules consisting of 2 to 6 repeated thiophene, acene molecules consisting of 2 to 6 condensed benzene rings, and molecules obtained by combining them:

(2) monovalent groups containing π electron conjugated system molecules which are molecules consisting of 2 to 6 repeated thiophene:

(3) monovalent groups containing π electron conjugated system molecules which are acene molecules consisting of 2 to 6 condensed benzene rings: and

(4) monovalent groups containing π electron conjugated system molecules each of which contains at least two or more molecules selected from molecules consisting of 2 to 6 repeated benzene, molecules consisting of 2 to 6 repeated thiophene, and acene molecules consisting of 2 to 6 condensed benzene rings.

Further, a vinylene group may be inserted between the units. Examples of hydrocarbons which derive a vinylene group are alkenes, alkadienes, and alkatrienes. Examples of alkenes are compounds having 2 to 4 carbon atoms such as ethylene, propylene, butylene and the like. Ethylene is particularly preferable. Examples of alkadienes are compounds having 4 to 6 carbon atoms such as butadiene, pentadiene, hexadiene and the like. Examples of alkatrienes are compounds having 6 to 8 carbon atoms such as hexatriene, heptatriene, octatriene and the like.

Further, compounds for obtaining the organic group R¹ may be compounds each consisting of two or more bonded units derived from condensed aromatic compounds, and compounds each consisting of a unit derived from a condensed aromatic compound and a unit derived from a monocyclic aromatic compound and/or a monocyclic heterocyclic compound and bonded with the former unit.

These organic groups may have functional groups at their terminals. Practical examples of the functional groups may be hydroxyl group, substituted or unsubstituted amino group, nitro group, cyano group, substituted or unsubstituted alkyl group, substituted or unsubstituted alkenyl group, substituted or unsubstituted cycloalkyl group, substituted or unsubstituted alkoxyl group, substituted or unsubstituted aromatic hydrocarbon group, substituted or unsubstituted aromatic heterocyclic group, substituted or unsubstituted aralkyl group, substituted or unsubstituted aryloxy group, substituted or unsubstituted alkoxycarbonyl group, carboxyl group, ester group, trialkoxysilyl group and the like. From a viewpoint that crystallization of the organic thin film is not inhibited by the steric hindrance, straight chain alkyl groups having 1 to 30 carbon atoms are particularly preferable and straight chain alkyl groups having 1 to 3 carbon atoms are even more preferable among these functional groups.

The functional groups may also be monovalent groups derived from condensed heterocyclic compounds having 2 to 8 condensed 5-member and/or 6-member rings. Examples of the condensed heterocyclic compounds are compounds defined by the following formulas (a) to (f)
Formula (a); 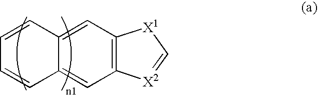
In the formula, X¹, X², and n1 are same as defined above.
Formula (b); 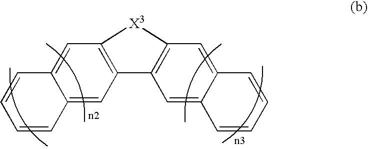
In the formula, X³, n2, and n3 are same as defined above.
Formula (c); 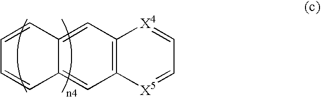
In the formula, X⁴, X⁵, and n4 are same as defined above.
Formula (d); 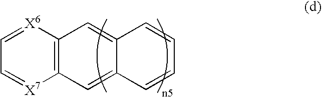
In the formula, X⁶, X⁷, and n5 are same as defined above.
Formula (e); 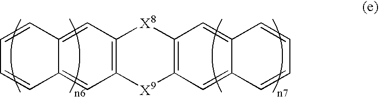
In the formula, X⁸, X⁹, n6, and n7 are same as defined above.
Formula (f); 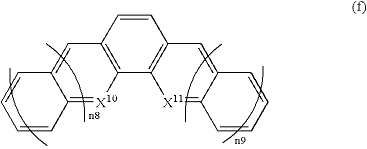
In the formula, X¹⁰, X¹¹, n8, and n9 are same as defined above.

Further, R¹ may have a side chain. The side chain may be any group as long as the group does not react with the neighboring molecules. Examples of the side chain are (un)substituted alkyl group, halogenated alkyl group, cycloalkyl group, aryl group, diarylamino group, di- or triarylalkyl group, alkoxy group, oxyaryl group, nitryl group, nitro group, ester group, trialkylsilyl group, triarylsilyl group, phenyl group, and acene group. In consideration of use of the compound as the organic thin film material and the significant intermolecular action with neighboring molecules, particularly preferable examples are alkyl group having 1 to 4 carbon atoms, trialkylsilyl group obtained by substituting silyl group with alkyl group having 1 to 4 carbon atoms, secondary or tertiary hydrocarbon group consisting of alkyl group having 1 to 4 carbon atoms, phenyl group, naphthalene, anthracene having 1 to 4 benzene rings, and tertiary amino group consisting of alkyl group having 1 to 4 carbon atoms.

The bonding position of the silyl group (SiZ¹Z²Z³) to the organic group R¹ is not particularly limited and may be any position where the silyl group can be bonded.

Preferable examples of the organic silane compound are as follows.

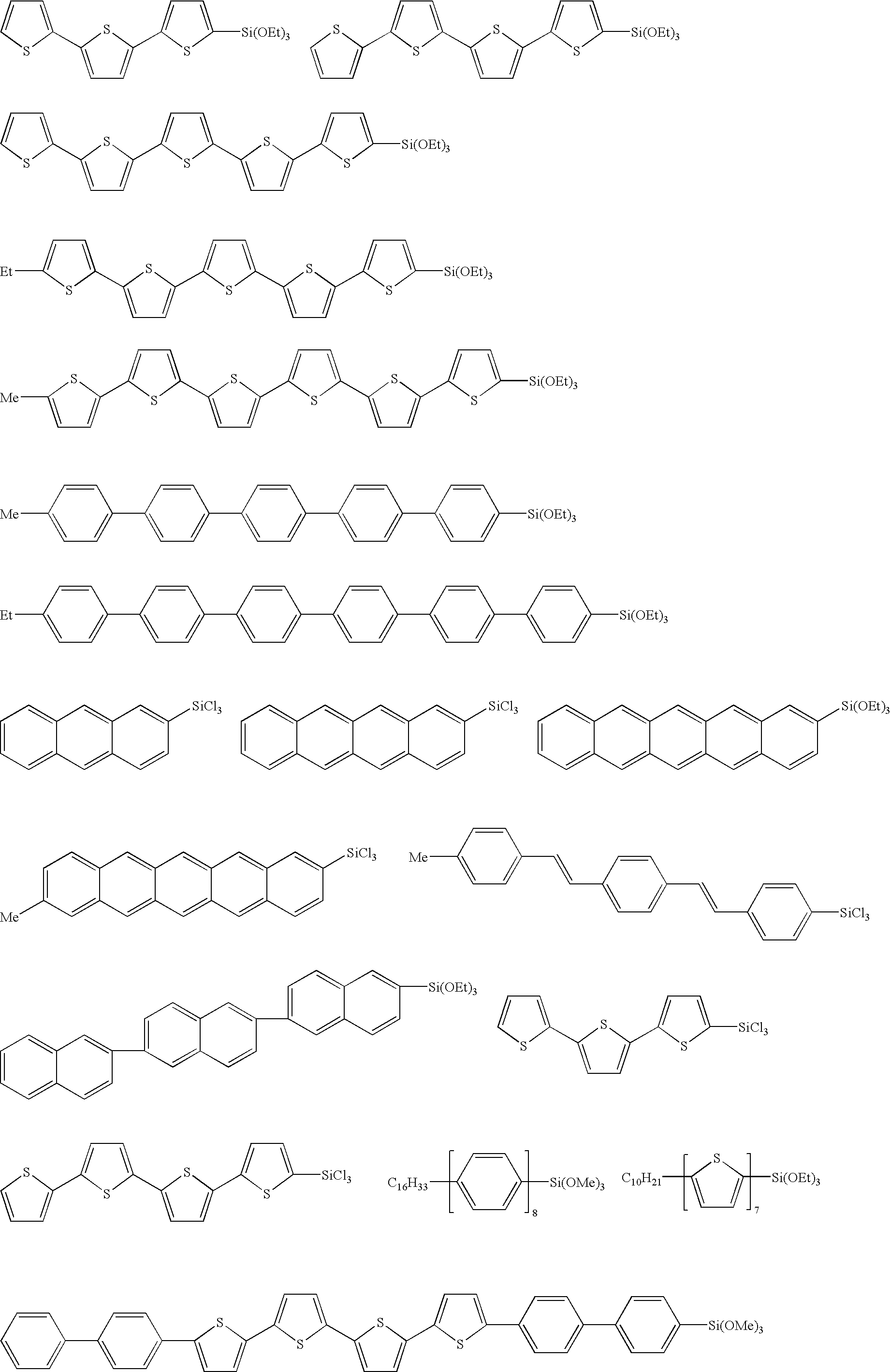

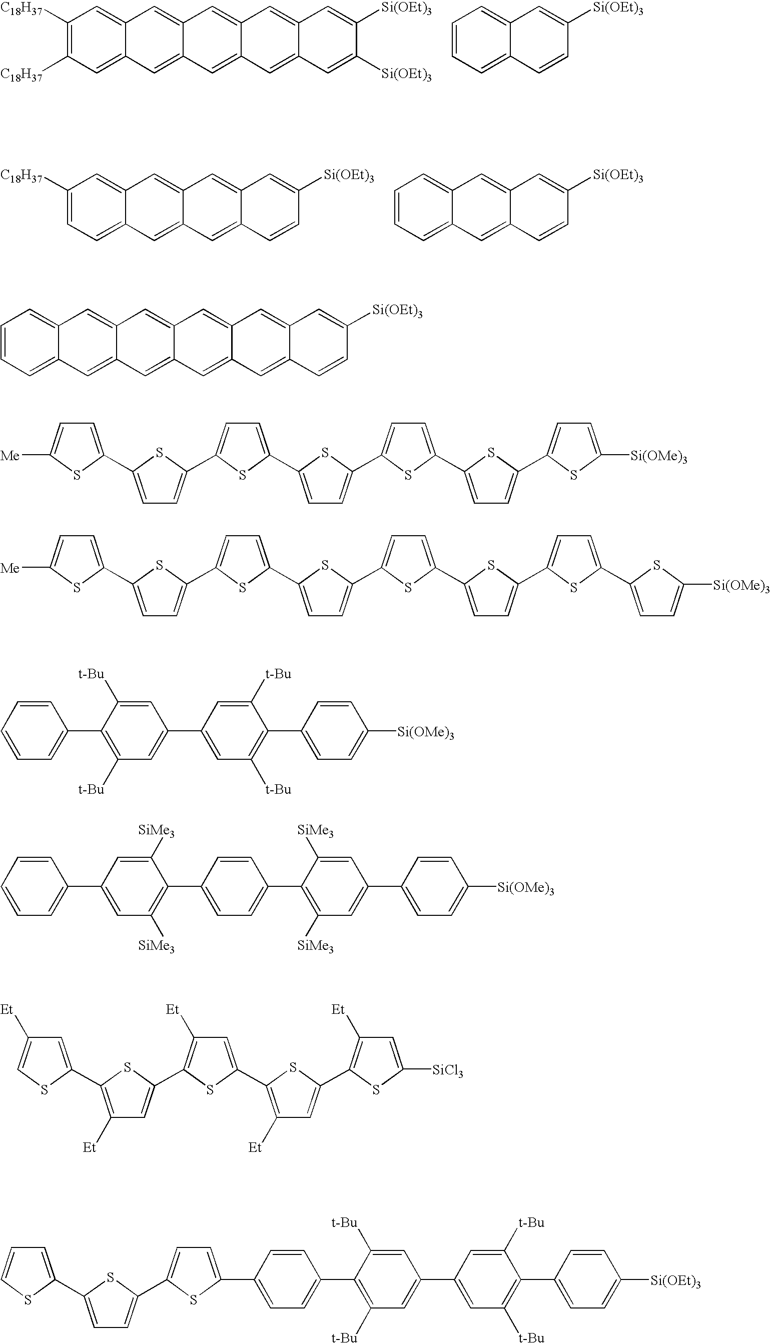

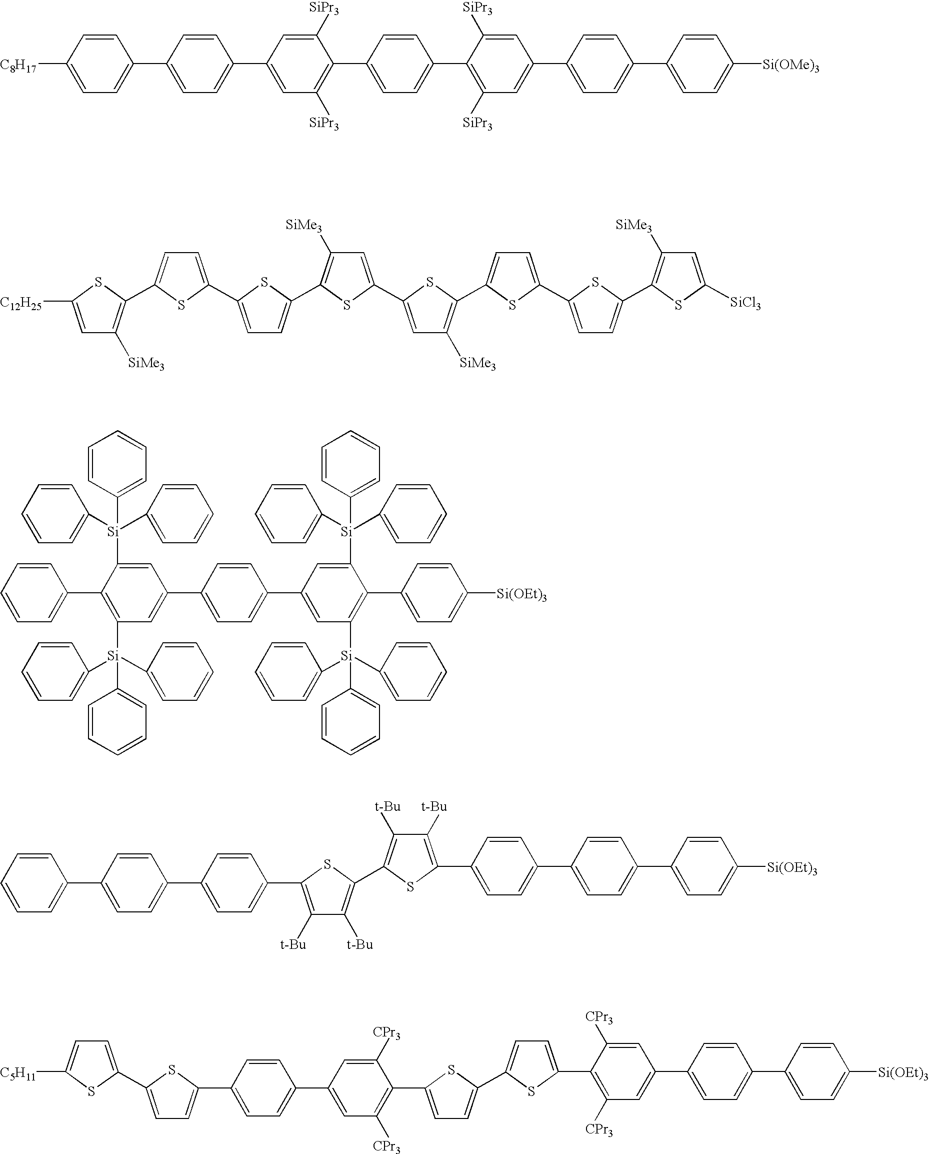

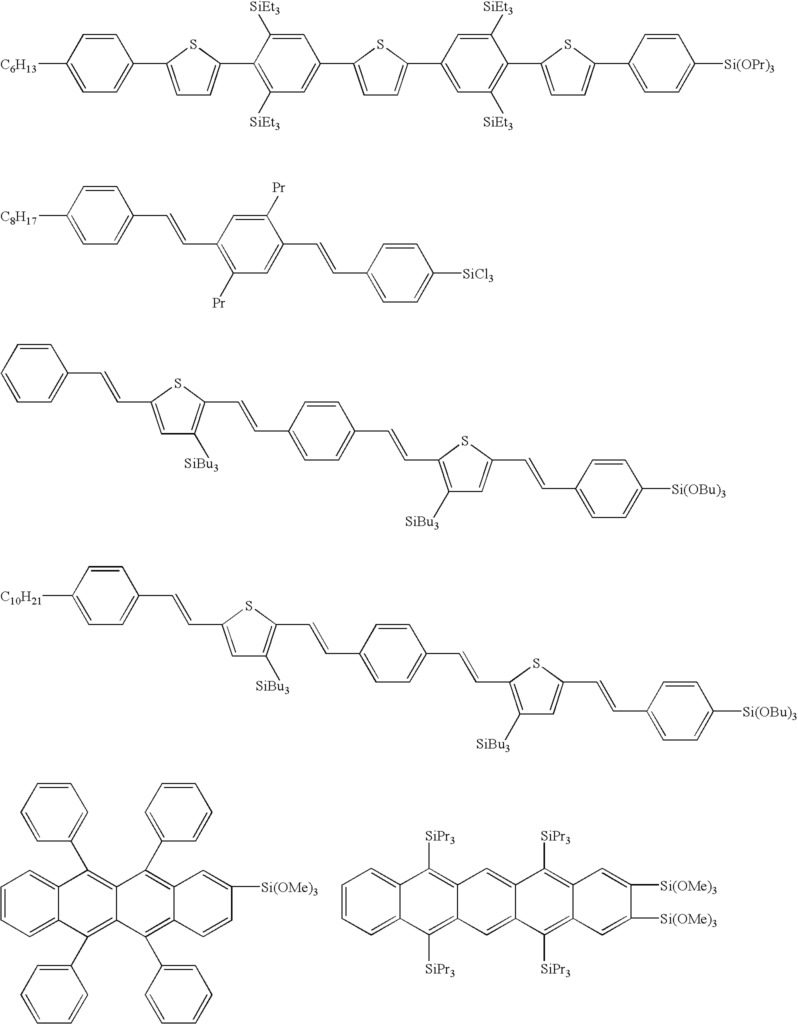

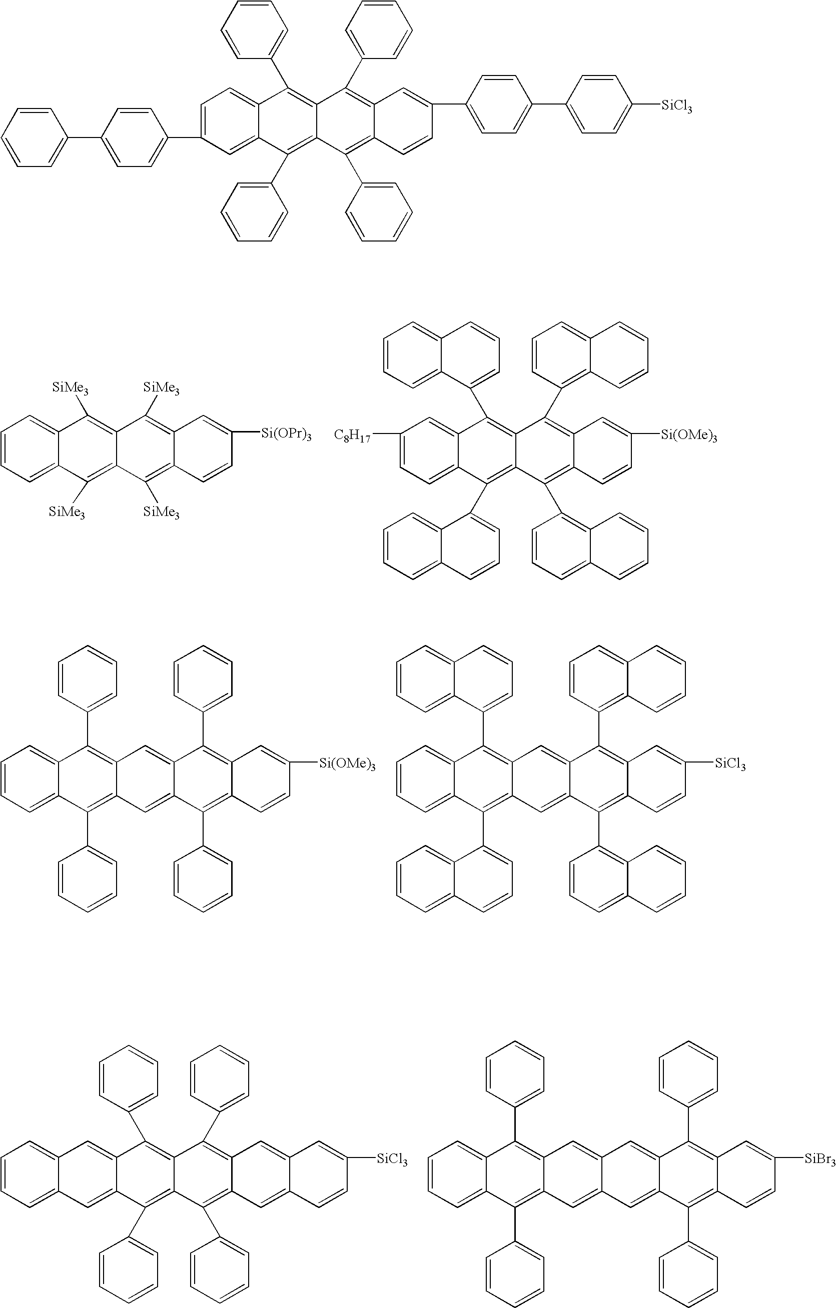

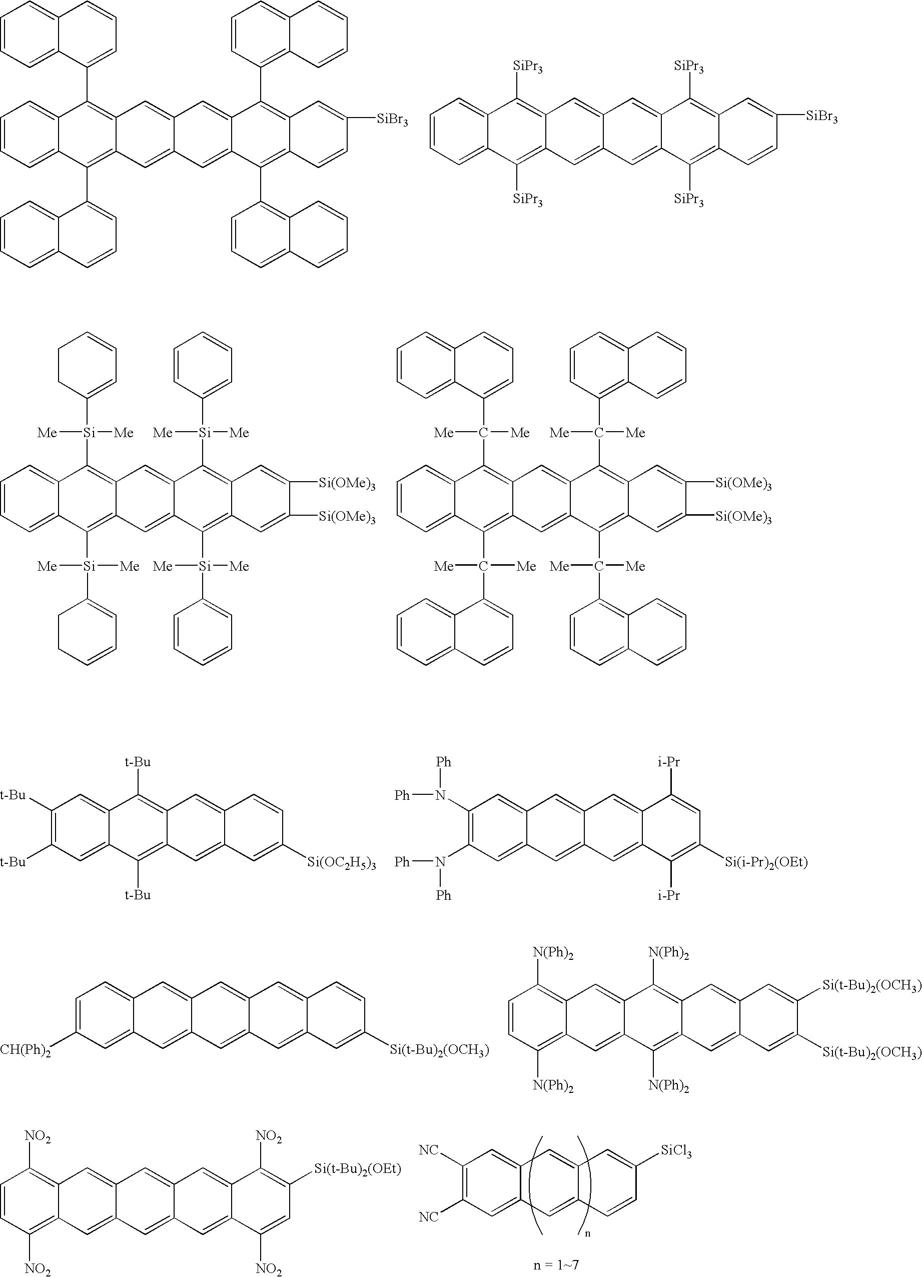

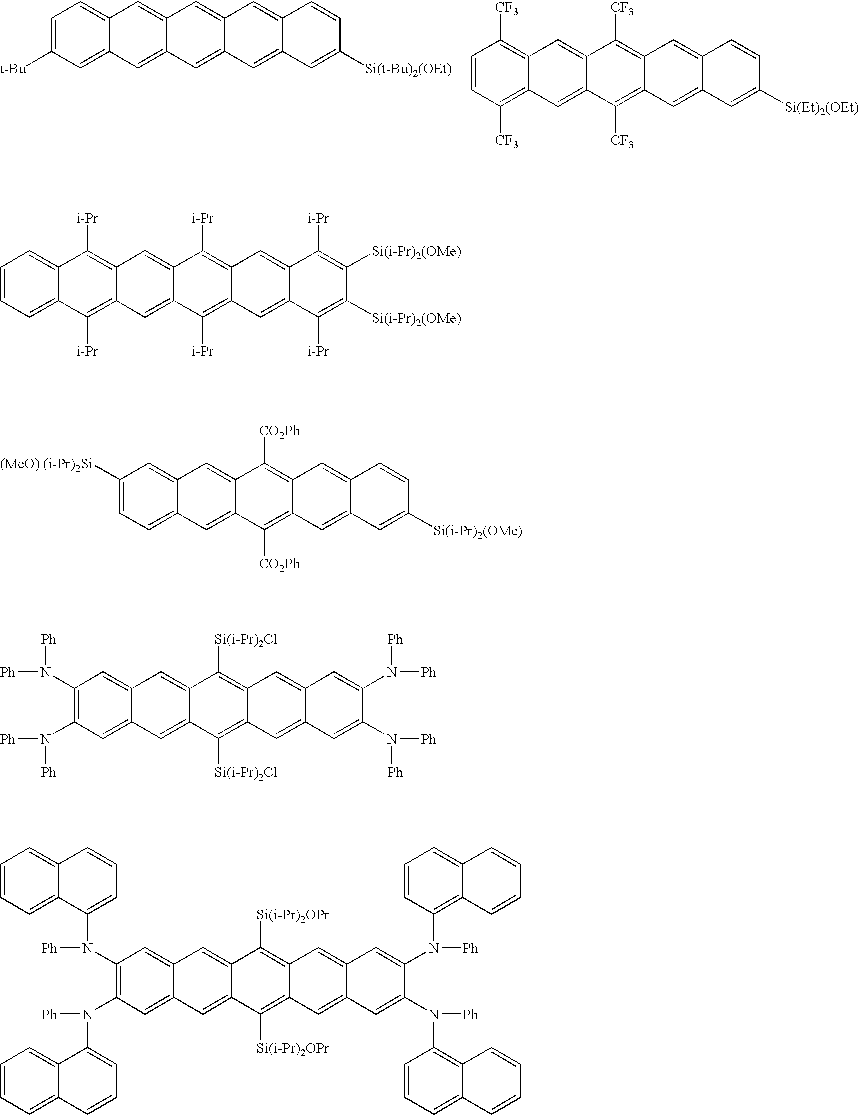

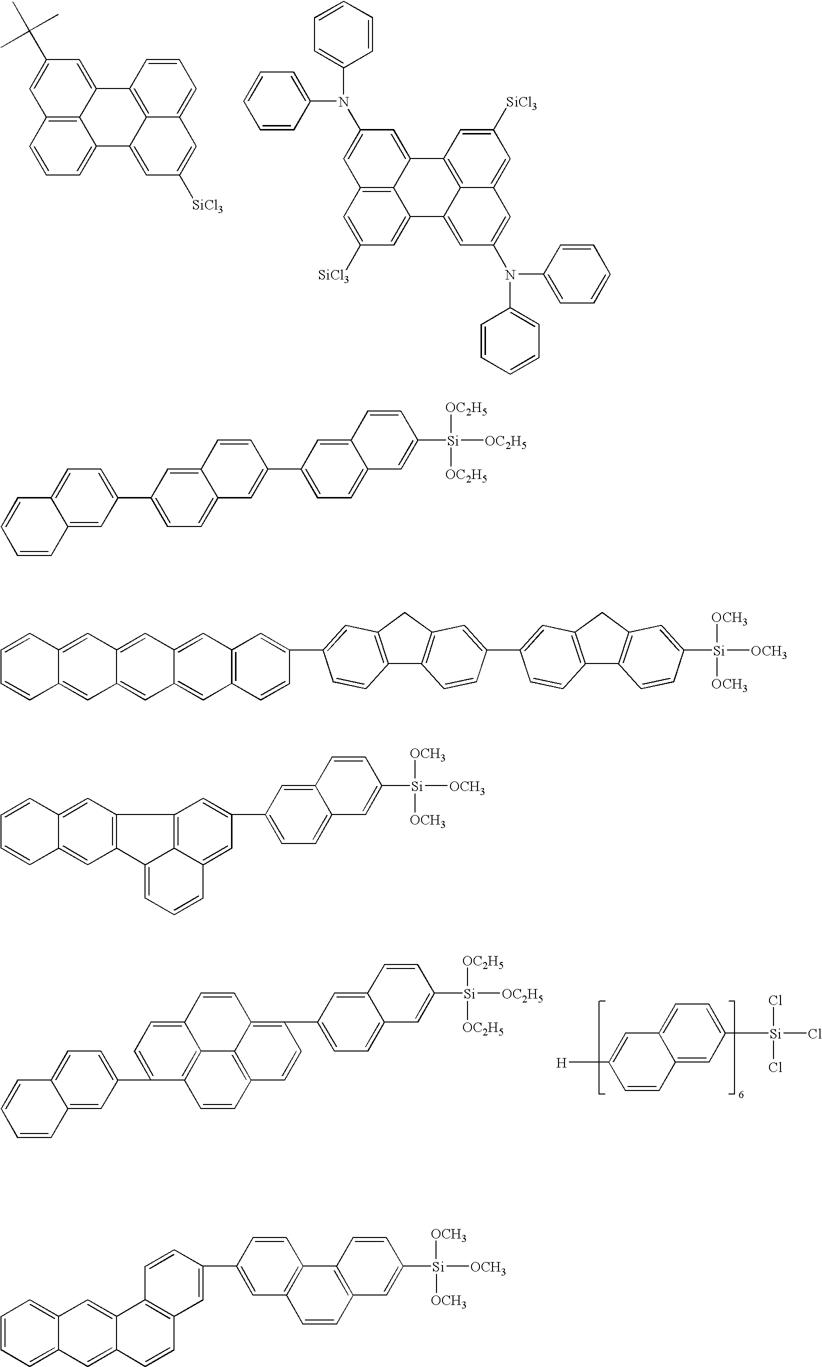

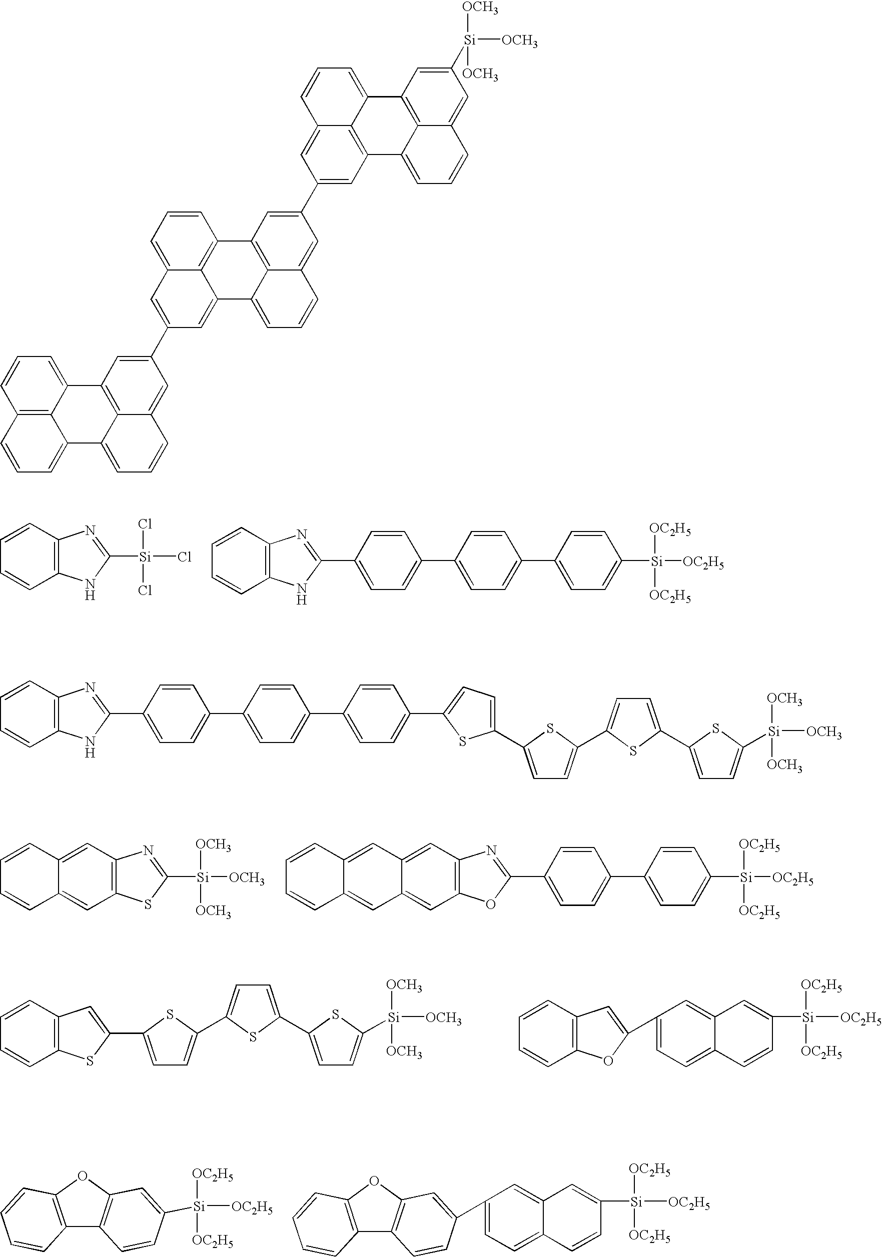

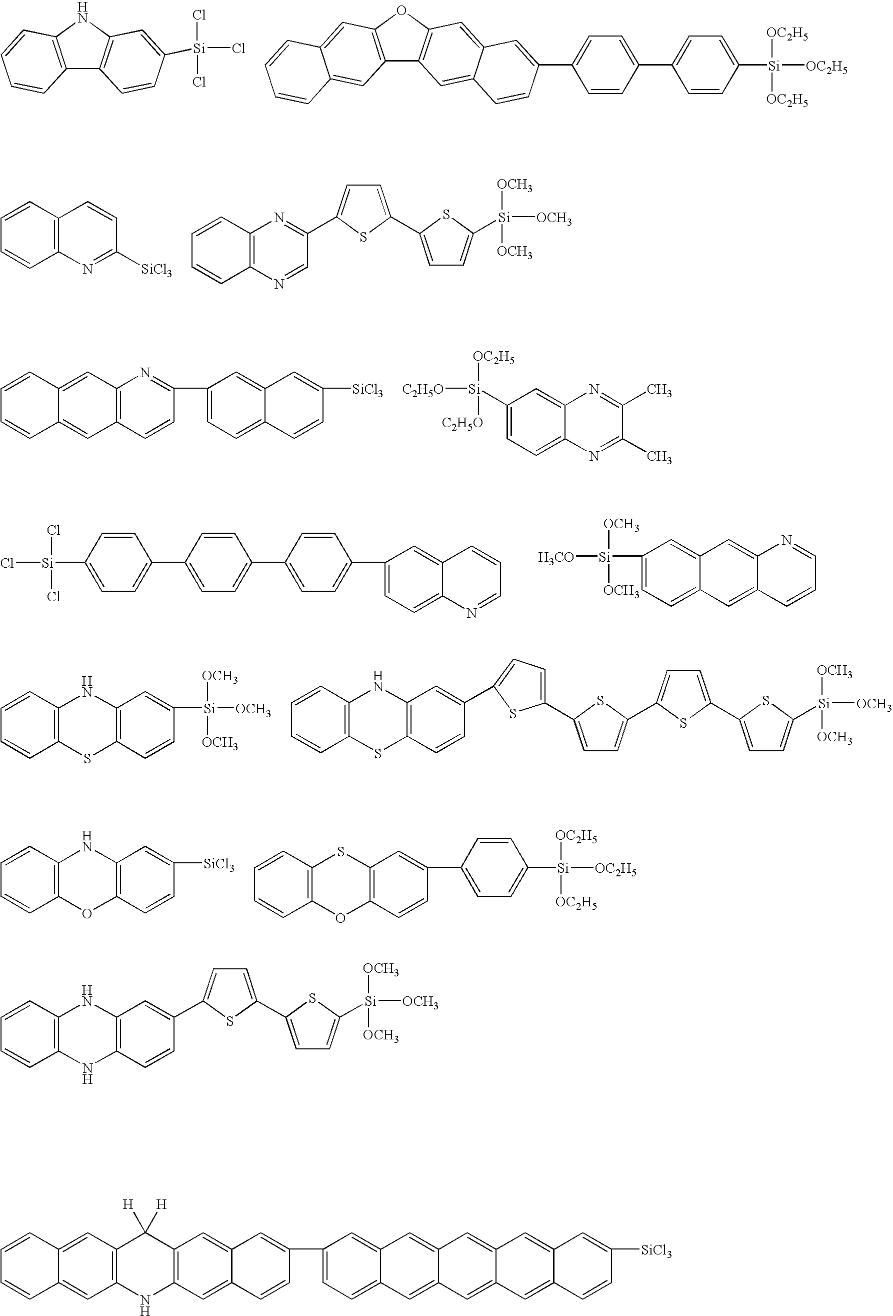

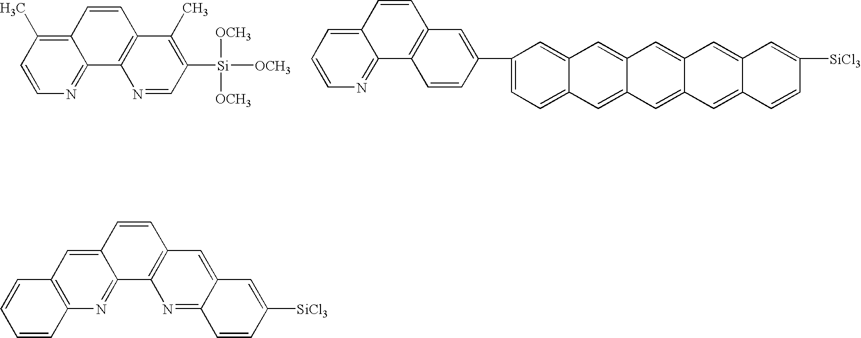

The organic silane compound can be synthesized by introducing a silyl group into a molecule containing the above-mentioned organic group R¹. The introduction position of the silyl group is not particularly limited if a monomolecular film to be obtained can retain molecular crystallinity where molecules are orderly arranged.

Silylation of the organic group R¹-containing molecule can be carried out by various conventionally known techniques. Examples of the techniques are (1) reaction of a corresponding Grignard reagent or a lithium reagent produced from a compound containing a halogen atom such as bromine, chlorine, or iodine with an organic silane compound containing halogen or alkoxy; (2) hydrosilation reaction by heating and stirring a corresponding compound having carbon-carbon multiple bonds and an organic silane compound containing at least one hydrogen atom on a silicon atom in the presence of a catalyst such as chloroplatinic acid etc.; and (3) reaction for synthesizing a substituted olefin by cross-coupling a corresponding vinyl borane compound and an organic halogenated silane compound using a palladium catalyst.

More particular examples of the techniques for the method (1) are as follows.

Reaction of a compound defined by the following formula:
R¹—MgX (2)
(wherein R¹ is as described above; and X denotes a halogen atom) and a compound defined by the following formula: Y¹—SiZ¹Z²Z³ (wherein Y¹ denotes a halogen atom; and Z¹ to Z³ are the same as defined above) (e.g. tetrachlorosilane, or triethoxyhalogenosilane) is caused to obtain an organic silane compound defined by the following formula:
R¹—SiZ¹Z²Z³ (4).
In the above-mentioned method, the halogen atom may be a chlorine atom, a bromine atom, and an iodine atom.

The reaction temperature at the time of the above-mentioned synthesis is preferably, for example −100 to 150° C. and more preferably −20 to 100° C. The reaction time is, for example, about 0.1 to 48 hours for every step. The reaction is generally carried out in an organic solvent which causes no effect on the reaction under a water-free condition. Examples of the organic solvent which does not cause any adverse effect on the reaction may be aliphatic or aromatic hydrocarbons such as hexane, pentane, benzene, toluene and the like; ether type solvents such as diethyl ether, dipropyl ether, dioxane, tetrahydrofuran (THF) and the like; and chloro hydrocarbons such as methylene chloride, chloroform, carbon tetrachloride and the like. These solvents may be used alone or in form of a mixture. Particularly, diethyl ether and THF are preferable. Reaction may be carried out optionally using a catalyst. Examples to be used as the catalyst are conventionally known catalysts such as a platinum catalyst, a palladium catalyst, a nickel catalyst and the like.

One example of a synthesis method of a compound containing two or more monocyclic aromatic compounds and/or monocyclic heterocyclic compounds bonded one another or a compound having an acene skeleton, which is preferable as a precursor of the organic group R¹, will be described.

(1) Compound Containing Two or More Monocyclic Aromatic Compounds and/or Monocyclic Heterocyclic Compounds Bonded One Another

As a synthesis method of a compound consisting of units derived from benzene, which is a monocyclic aromatic compound, or thiophene, which is a heterocyclic compound, a method of employing the Grignard reaction after halogenation of the reaction position of benzene or thiophene is effective. If the method is employed, a compound with a controlled number of benzene or thiophene can be synthesized. The synthesis may be carried out by coupling using a proper metal catalyst (Cu, Al, Zn, Zr, Sn or the like) other than the method using the Grignard reagent.

Further, in the case of using thiophene, the following synthesis method may be employed besides the method using the Grignard reagent.

That is, first, halogenation (e.g. bromination or chlorination) at 2- or 5-position of thiophene is carried out. A method for halogenation may be, for example, treatment with one equivalent of N-chlorosuccinimide (NCS) or N-bromosuccinimide (NBS) or treatment with phosphorus oxychloride (POCl₃). Examples of a solvent to be used in this case may be a chloroform-acetic acid (AcOH) mixture, DMF, and carbon tetrachloride. Alternatively, halogenated thiophene molecules may be reacted in a DMF solvent using tris(triphenylphosphine)nickel(PPh₃)3Ni) as a catalyst to consequently carry out direct bonding of the thiophene molecules at the halogenated positions.

Further, coupling is carried out for halogenated thiophene by adding divinylsulfone to form a 1,4-diketone compound. Successively, Lawesson Regent (LR) or P₄S₁₀ is added in a dry toluene solution and the contents are refluxed overnight in the case of the former and for about 3 hours in the case of the latter to cause a ring closing reaction. As a result, a compound with a number of thiophene rings higher by one than the total of the coupled thiophene rings can be synthesized.

The number of the thiophene rings can be increased by the above-mentioned reaction of thiophene.

The above-mentioned compound may be halogenated at the terminal similarly to the raw material used for the synthesis. Therefore, after the halogenation of the compound, reaction with, for example, SiCl₄ may be carried out to obtain a silane compound (simple benzene or simple thiophene compound) having an organic residual group consisting only of units derived from benzene or thiophene and having a silyl group at the terminal.

Additionally, synthesis examples of the compounds (A) to (C) consisting of only benzene or thiophene will be described below. In the synthesis example of the following compound (A) consisting of only thiophene, only the reaction from a trimer of thiophene to a hexamer or heptamer is described. However, if reaction of thiophene with a different number of units is carried out, compounds other than the hexamer or heptamer can be synthesized. For example, a tetramer or pentamer of thiophene can be obtained by, for example, coupling 2-chlorothiophene and successively carrying out the reaction with 2-chlorobithiophene chlorinated by NCS in the same manner as described below. Further, an octamer or nanomer may also be synthesized by chlorinating a thiophene tetramer by NCS.

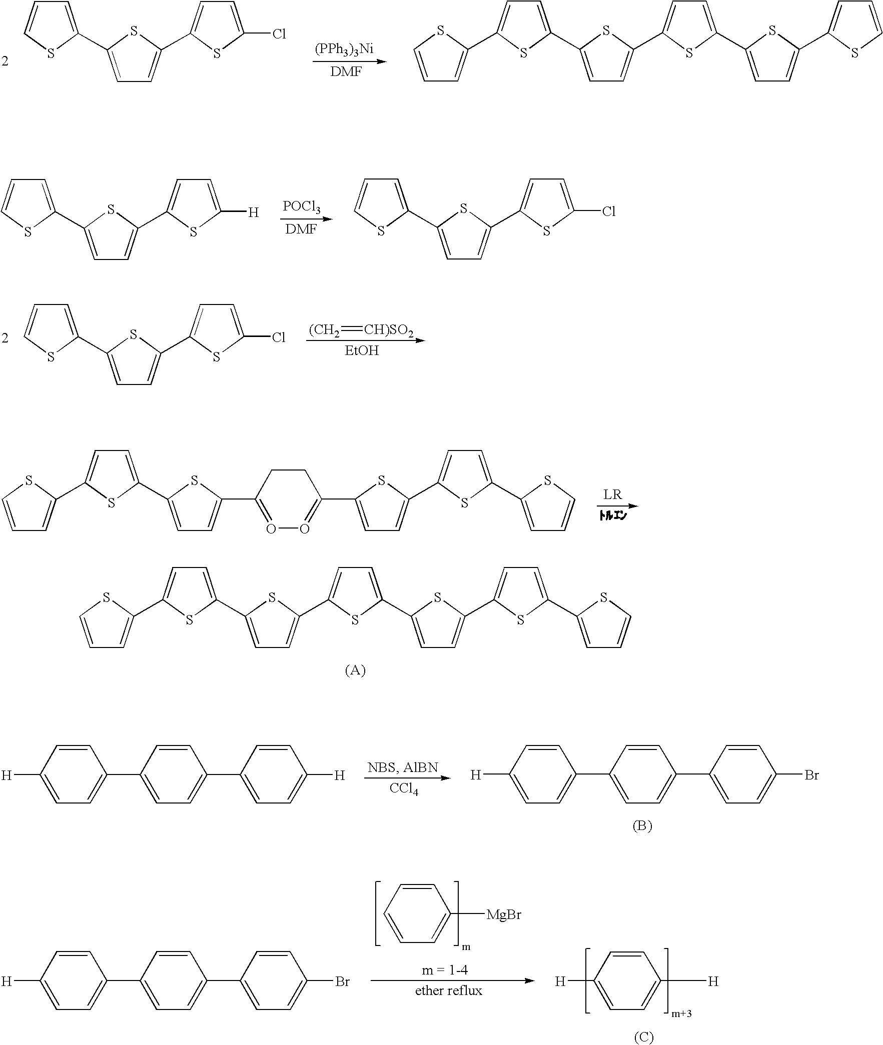

A method for obtaining a block type compound by directly bonding units, which are obtained by bonding prescribed numbers of units derived from thiophene and benzene one another, may be a method employing, for example, the Grignard reaction. The following method may be employed as a synthesis example in this case.

First, after halogenation (e.g., bromination) is carried out at a prescribed position of a simple benzene or a simple thiophene compound, n-BuLi and B(O-iPr)₃ are added to carry out debromination and boron formation. A solvent to be used in this case is preferably an ether. The reaction for boron formation is carried out in two-steps and in order to stabilize the reaction at the initial stage, it is preferable to carry out the first step at −78° C. and the second step at a temperature gradually increased to a room temperature from −78° C. On the other hand, an intermediate of the block type compound is previously produced by the Grignard reaction of benzene or thiophene having halogen atoms (e.g. bromine atoms) at both terminals.

In such a situation, it is possible to cause coupling by developing an unreacted bromo group and the above-mentioned boron compound in, for example, a toluene solvent and completely promoting the reaction at a reaction temperature of 85° C. in the presence of Pd(PPh₃)₄ and Na₂CO₃. As a result, the block type compound can be synthesized.

Synthesis examples of the compounds (D) and (E) by such a reaction will be described blow.

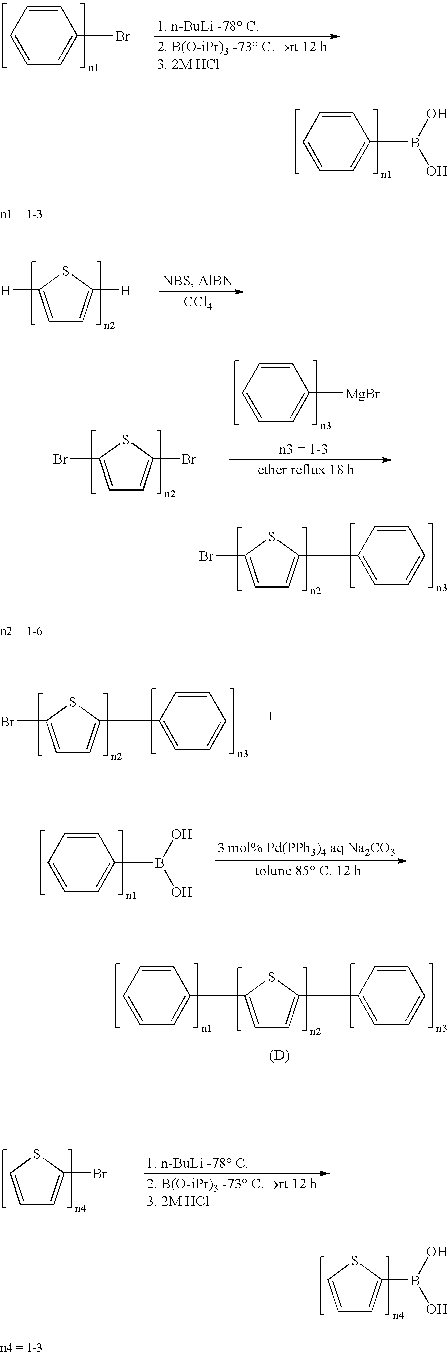

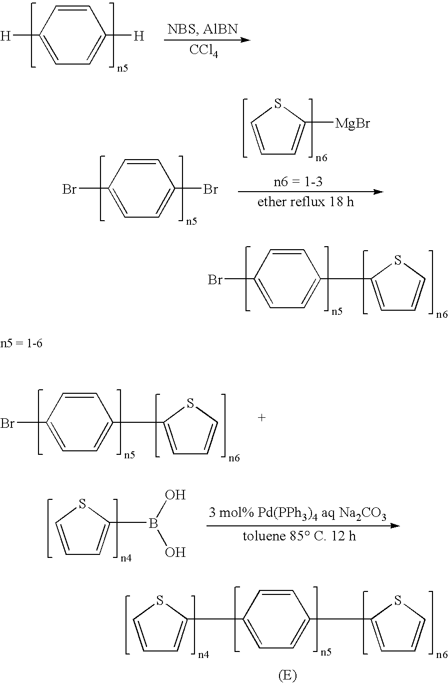

The following method can be employed as a method for synthesizing a compound in which units derived from benzene or thiophene and vinyl groups are reciprocally bonded. That is, after a raw material having a methyl group at a reaction position of benzene or thiophene is prepared, both ends are brominated using 2,2′-azobisisobutyronitrile (AIBN) and NBS. After that, reaction of PO(OEt)₃ with the bromo-compound is carried out to form an intermediate. Successively, reaction of a compound having an aldehyde group at the terminal and the intermediate is caused in, for example, a DMF solvent using NaH to synthesize the above-mentioned compound. Since the obtained compound has a methyl group at the terminal, if the methyl group is further brominated and the above-mentioned synthesis process is again carried out, a compound with an increased number of the units can be synthesized.

Synthesis examples of the compounds (F) to (H) with different lengths by such a reaction are shown below.

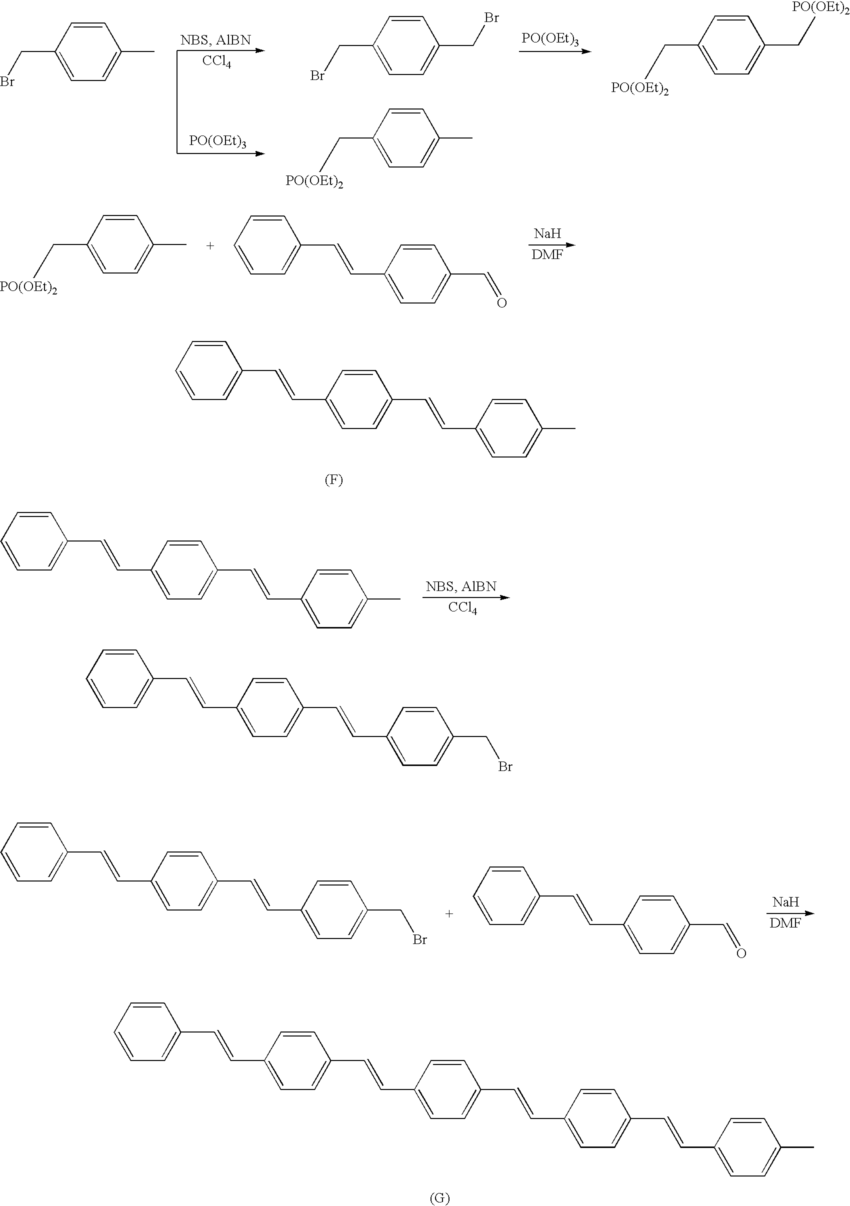

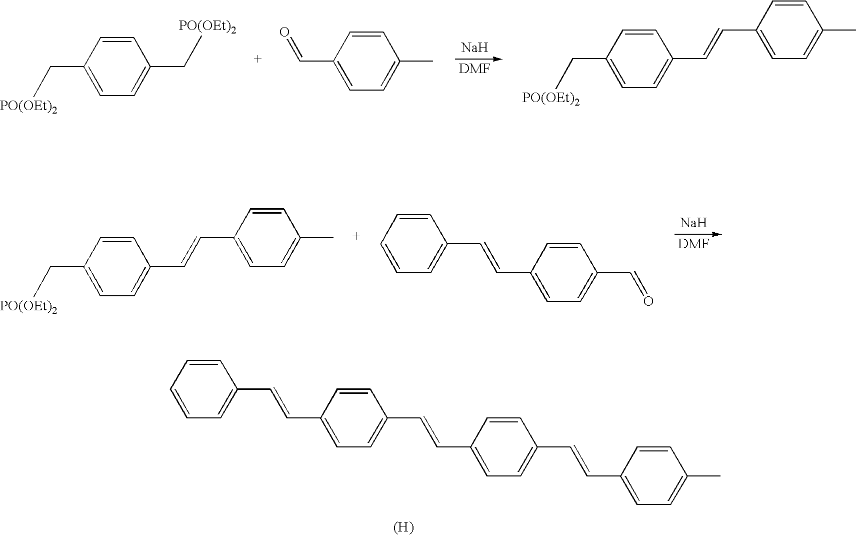

With respect to all of the compounds, raw materials having a side chain (e.g., alkyl group) at a prescribed position can be used. That is, for example, if 2-octadecylterthiophene is used as a raw material, 2-octadecylsexi-thiophene is obtained as the compound (A) by the above-mentioned synthesis process. Similarly, if a raw material preliminary having a functional group or a side chain at a prescribed position is used, a compound, which is one of the above-mentioned compounds (A) to (H), having the functional group or the side chain can be obtained.

Additionally, the raw materials used for the above-mentioned synthesis examples are commercialized reagents and thus made available from reagent manufacturers and made usable. Hereinafter, CAS numbers of the raw materials and the purities of the reagents in the case they are made available by a reagent manufacturer, for example, Kishida Chemical Co., Ltd. are shown.

TABLE 1

| Raw material | CAS No. | Purity |
|---|---|---|
| 2-chlorothiophene | 96-43-5 | 98% |
| 2,2′,5′,2″-terthiophene | 1081-34-1 | 99% |
| Bromobenzene | 108-86-1 | 98% |
| 1,4-dibromobenzene | 106-37-6 | 97% |
| 4-bromobiphenyl | 92-66-0 | 99% |
| 4,4′-dibromobiphenyl | 93-86-4 | 99% |
| p-terphenyl | 92-94-4 | 99% |
| α-bromo-p-xylene | 104-81-4 | 98% |

According to the above-mentioned synthesis method of the compound consisting of two or more monocyclic aromatic compounds and/or monocyclic heterocyclic compounds bonded one another, a condensed aromatic compound and a condensed heterocyclic compound can also be bonded with a monocyclic aromatic compound, a monocyclic heterocyclic compound, a condensed aromatic compound, and a condensed heterocyclic compound.

(2) Compound Having Acene Skeleton, Acenaphthene Skeleton, or Perylene Skeleton

As a synthesis method of the compound having an acene skeleton, for example, there are the following methods: (1) a method of repeating steps of substituting hydrogen atoms bonded to two carbon atoms at prescribed positions of a starting compound with ethynyl groups and successively carrying out ring-closing reaction of the ethynyl groups; and (2) a method of repeating steps of substituting a hydrogen atom bonded to a carbon atom at a prescribed position of a starting compound with a triflate group, causing reaction with furan or its derivative, and successively carrying out oxidation. Synthesis examples of the compounds (I) to (J) having an acene skeleton by these methods are shown below.

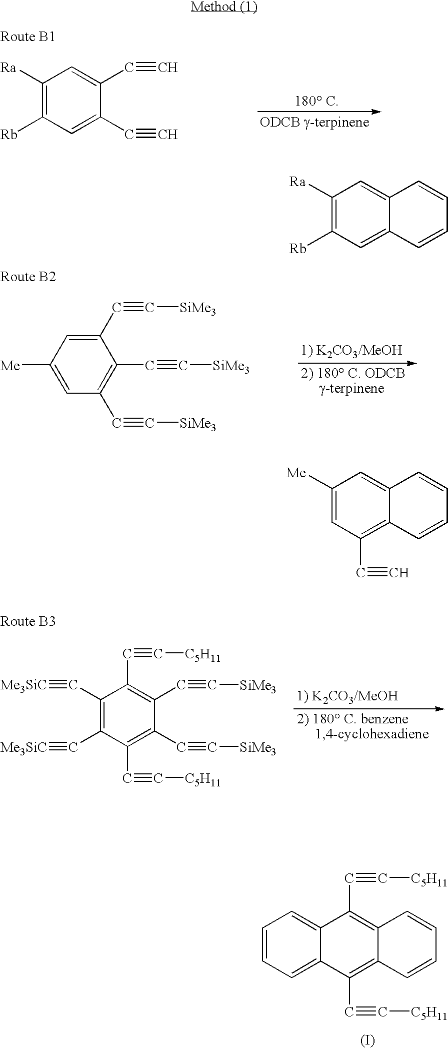

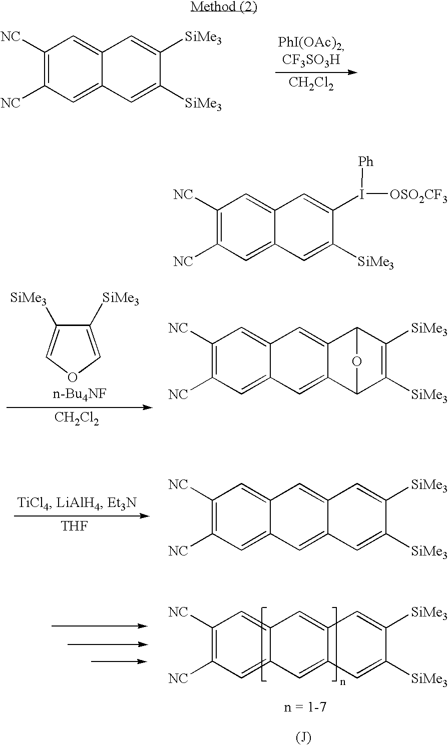

Further, since the above-mentioned method (2) is a method for increasing the benzene ring of the acene skeleton one by one, for example, even if the starting compound contains a side chain or a protection group with low reactivity at a prescribed part, the compound (K) having the acene skeleton can be synthesized similarly. A synthesis example in this case is shown below.

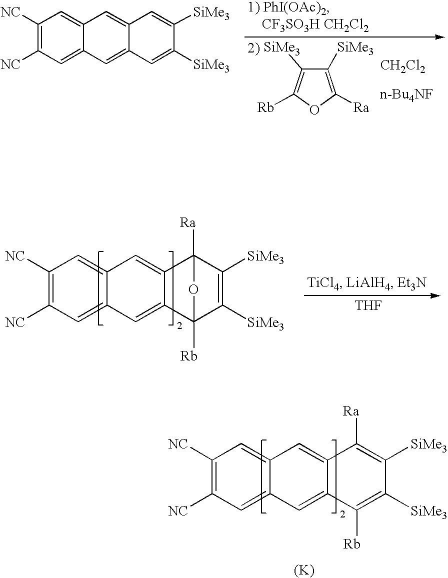

Herein, Ra and Rb are preferably a side chain or a protection group with low reactivity such as a hydrocarbon group, an ether group or the like.

In the reaction formula of the above-mentioned method (2), the starting compound having two acetonitryl groups and trimethylsilyl groups may be changed to a compound having trimethylsilyl groups in place of all of these groups. Further, in the above-mentioned reaction formula, a compound having benzene rings increased by one from that of the starting compound and having two substituent groups for hydroxyl groups can be obtained by carrying out reaction using a furan derivative and then refluxing the reaction product in the presence of lithium iodide and DBU (1,8-diazabicyclo[5.4.0]undec-7-ene).

The compounds (L) to (M) having an acenaphthene skeleton and a perylene skeleton can be synthesized as follows.

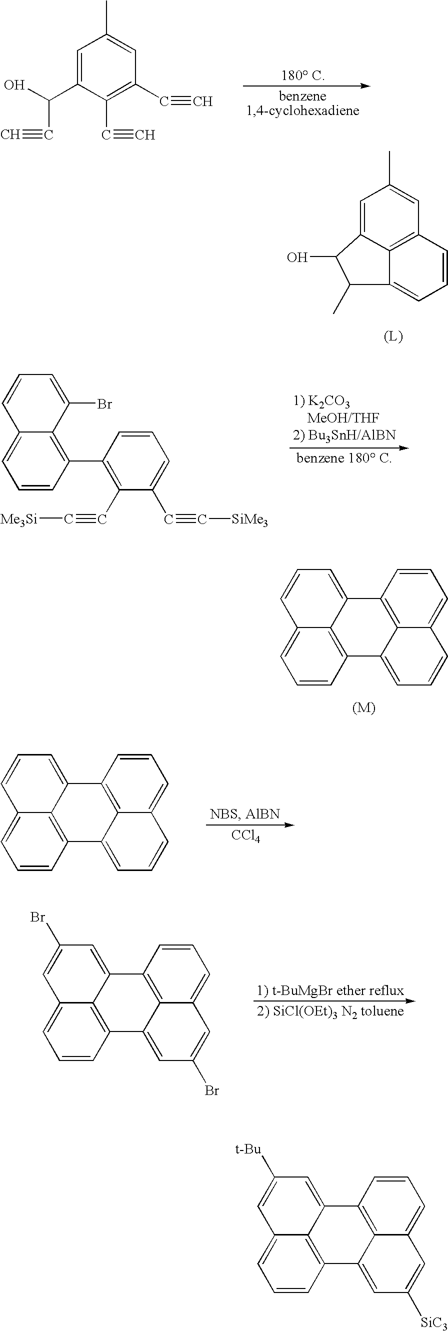

As a technique for inserting, as a side chain, a secondary amino group having two aromatic ring groups as substituents in a nitrogen atom into the perylene skeleton, there is a technique of coupling the above-mentioned secondary amino group in the presence of a metal catalyst after previous halogenation of the insertion part of the side chain. For example, in the case of the above-mentioned perylene molecule, the secondary amino group may be inserted by, for example, the following technique.

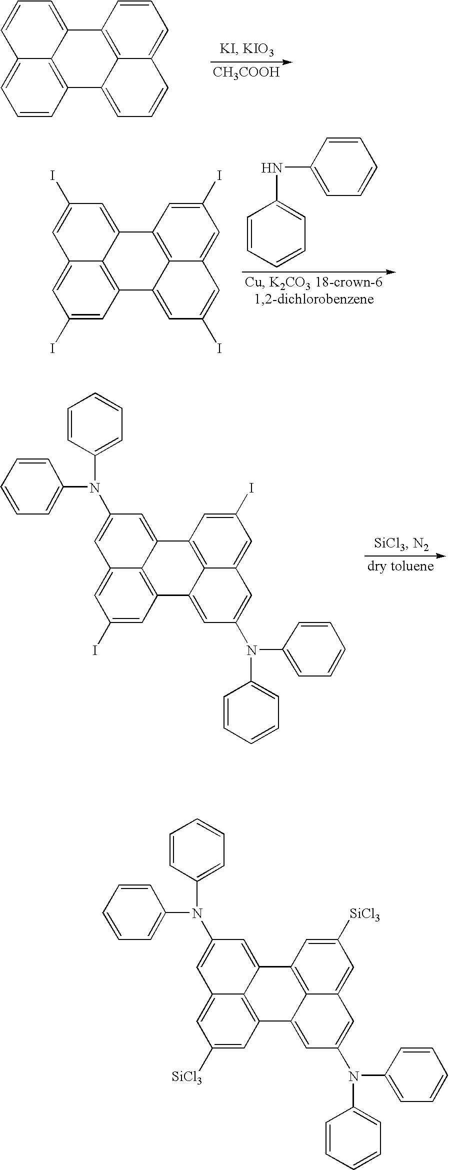

The starting materials used in the above-mentioned synthesis examples are commercialized reagents and made available from reagent manufacturers and made usable. For example, tetracene with 97% or higher purity is made available by Tokyo Kasei Co., Ltd.

The organic silane compounds can be isolated and refined from reaction solutions by conventionally known means, for example, dissolution in another solvent, concentration, solvent extraction, fractionation, crystallization, re-crystallization, and chromatography.

A formation method of a film of an organic silane compound is not particularly limited as long as a monomolecular film is formed. In consideration of the uniformity of the film surface of the organic silane compound, films with higher uniformity can be formed by an LB method, an immersion method, and a CVD method in this order. Further, a vapor-deposition method is also usable.

For example, an organic silane compound is dissolved in a water-free organic solvent such as hexane, chloroform, carbon tetrachloride or the like. A substrate on which a thin film is to be formed is immersed in the obtained solution (with a concentration of about 1 mM to 100 mM) and pulled out. Alternatively, the obtained solution may be applied to the substrate surface. After the substrate is washed with a non-aqueous organic solvent, it is washed with water, and kept still or heated for drying to fix an organic thin film. The thin film may be used as an organic thin film as it is or may be further subjected to a treatment such as electrolytic polymerization.

It is required that a functional group bonded to the silyl group is eliminated and replaced with a hydroxyl group or proton for bonding the organic silane compound through the silanol bond. The substituted silyl group is reacted with a hydroxyl group (or carboxyl group) on the gate insulating film surface to form the silanol bond.

Further, in the case neighboring Si atoms in the formula (1) are crosslinked by themselves or through oxygen atoms, the distance between neighboring units is narrowed and crystallization is carried out to a higher degree due to control of, for example, Si—O—Si network. Particularly, in the case the units are positioned in a straight chain, the neighboring units are not bonded but the distance between the neighboring units is minimized to obtain a material with high crystallinity. An anchor film exhibiting carrier transportation function in the surface direction of the substrate can be obtained by such orientation of the units. In other words, it is made possible to form an anchor film having electric anisotropy, that is, the electric properties different in the perpendicular direction and the surface direction to the substrate surface.

After the film of the organic silane compound is formed, it is preferable to remove the un-reacted organic silane compound from the film of the organic silane compound by washing using a non-aqueous solvent.

(d) Organic Thin Film

A material for the organic thin film may be materials conventionally known in this field and compounds obtained by removing a silyl group from the above-mentioned organic silane compounds. In consideration of the transistor operation or material supply, as the organic thin film material, the following low molecular weight compounds and polymer compounds are preferable.

The low molecular weight compounds are preferably compounds with a molecular weight of less than 1,000 and specific examples are acene obtained by condensing 3 to 10 benzene rings, oligothiophene comprising 3 to 10 repeated thiophene, oligophenylene comprising 3 to 10 repeated benzene, oligophenylene-vinylene comprising 1 to 10 repeated benzene and vinylene, and oligophenylenethiophene comprising 1 to 10 repeated benzene and thiophene.

The polymer compounds are preferably compounds having a number average molecular weight of 1,000 or higher and examples are compounds comprising, as repeating units, thiophene, phenylene-vinylene, and acene. Particularly preferable examples are naphthacene, pentacene, perylene, rubrene, quinquethiophene (α-5T), sextet-thiophene (α-6T), sextet-phenylene, oligophenylene-vinylene comprising 3 units, poly(3-hexylthiophene) (P3HT), polyphenylene-vinylene (PPV), and their derivatives.

Further, fullerene compounds such as fullerene (C60), C60-fused pyrrolidine-meta-C12 phenyl(C60MC12), and [6,6]-phenylC61-methyl butanate ester (PCBM) are also usable.

In the case of formation of the film using a single compound, it is made possible to use an organic thin film with a lower crystallinity as compared with that of the anchor film. If the crystallinity of the anchor film is high, the organic thin film is affected by the crystallinity of the anchor film and easily crystallized to obtain an organic thin film transistor with high electron mobility.

All the common techniques of forming an organic thin film such as a SAM method (e.g., an LB method, vapor-deposition, dipping, immersion, casting, and a CVD method) can be employed for an organic thin film formation method and may be properly set in consideration of the cost of materials and mass production.

In this specification, the SAM method, LB method, vapor-deposition method, dipping method, immersion method, casing method, and CVD method are defined as follows.

The SAM method is an abbreviation for Self-Assembled Monolayer and means a technique of forming a film using materials which are capable of self organization and includes the LB method, dipping method (dip method), casting method, and CVD method.

The LB method is an abbreviation for Langmuir-Blodgett method and means a technique of forming a film of a single molecular layer, so-called as a monomolecular film by spreading an amphoteric substance with good balance between hydrophobic groups and hydrophilic groups on water surface and transferring the film to a substrate.

The vapor-deposition method is a method involving heating a raw material for producing vapor and depositing the raw material on a desired region and in the case of an organic semiconductor material, a vapor-deposition method by resistance heating can be employed.

The dipping method (dip method) is a method of forming a film by immersing a substrate in a certain solution and successively pulling out the substrate and in the case of using a material having crystallinity, a crystal with a characteristic structure can be grown.

The casting method means a method of forming a film by dropwise dripping a solution containing a raw material to a desired region and drying the solution and ink-jet is also included.

The CVD method means a method of heating/evaporating a solution in a closed container or a closed space and adsorbing the evaporated molecules on the substrate surface in the vapor phase.

(Fabrication Method of Organic TFT)

A fabrication method of an organic TFT may be any method as long as it includes a step of forming a film of an organic silane compound between the above-mentioned organic thin film and gate insulating film and/or between the organic thin film and source/drain electrodes.

In the case, for example, the organic TFT comprises an anchor film, the fabrication method may include the following:

(1) a method involving steps of forming a gate electrode on a substrate, forming a gate insulating film on the gate electrode, forming an anchor film, which is a monomolecular film having a carrier transportation function and formed on the gate insulating film using an organic silane compound, forming an organic thin film on the anchor film, and forming source/drain electrodes on the anchor film before formation of the organic thin film or forming the source/drain electrodes on the organic thin film;

(2) a method involving steps of forming source/drain electrodes on a substrate, forming an organic thin film on the source/drain electrodes, forming an anchor film, which is a monomolecular film having a carrier transportation function and formed on the organic thin film using an organic silane compound, forming a gate insulating film on the anchor film, and forming a gate electrode on the gate insulating film; and

(3) a method involving steps of forming an organic thin film on a substrate, forming source/drain electrodes on the organic thin film, forming an anchor film, which is a monomolecular film having a carrier transportation function and formed on the organic thin film between the source/drain electrodes using an organic silane compound, forming a gate insulating film on the anchor film, and forming a gate electrode on the gate insulating film. A preferable method among these methods is the method (1) in which the crystallinity of the organic thin film can be easily adjusted by the anchor film.

Further, in the case the organic TFT comprises a buffer film, the fabrication method may include the following:

(4) a method involving steps of forming a gate electrode on a substrate, forming a gate insulating film on the gate electrode, forming a buffer film, which is a monomolecular film having a carrier transportation function and formed on the gate insulating film using an organic silane compound, forming source/drain electrodes on the buffer film, and forming an organic thin film on the buffer film between the source/drain electrodes;

(5) a method involving steps of forming source/drain electrodes on a substrate, forming a buffer film, which is a monomolecular film having a carrier transportation function and formed on the source/drain electrodes using an organic silane compound, forming an organic thin film on the buffer film, forming a gate insulating film on the organic thin film, and forming a gate electrode on the gate insulating film; and

(6) a method involving steps of forming an organic thin film on a substrate, forming a buffer film, which is a monomolecular film having a carrier transportation function and formed on the organic thin film using an organic silane compound, forming source/drain electrodes on the buffer film, forming a gate insulating film on the buffer film between the source/drain electrodes, and forming a gate electrode on the gate insulating film. Preferable methods among these methods are the methods (4) and (5) in which the crystallinity of the organic thin film can be easily adjusted by the buffer film.

The methods (1) and (3); (2) and (4); and (3) and (6) may be combined, respectively.

### EXAMPLES

### Example 1

To fabricate an organic TFT shown in FIG. 1, chromium was first vapor-deposited on a substrate 1 of silicon to form a gate electrode 2.

Next, after a gate insulating film 3, which was a silicon nitride film, was deposited by a plasma CVD method, vapor-deposition of chromium and gold is carried out in this order and source/drain electrodes (5, 7) were formed by a conventional lithographic technique.

Successively, the obtained substrate was immersed in a mixed solution of hydrogen peroxide and concentrated sulfuric acid (mixing ratio 3:7) for 1 hour to make the surface of the gate insulating film 3 hydrophilic. After that, the obtained substrate was immersed in a 20 mM solution obtained by dissolving pentacene-triethoxysilane in a non-aqueous solvent (e.g. n-hexadecane) for 5 minutes in an aerobic condition, slowly pulled out of the solution, and washed with a solvent to form an anchor film 4. Successively, the resulting substrate was introduced into vacuum and a pentacene thin film with a thickness of 100 nm was vapor-deposited in a condition of a vacuum degree of 1×10⁻⁶ Torr and a vapor-deposition speed of 10 Å/min to form an organic thin film 6 and accordingly an organic TFT was fabricated.

When the formed organic thin film was observed by an atomic force microscope to confirm the morphology, Φ4 μm of dendrite type grains attributed to the pentacene vapor-deposited film were observed.

Further, the obtained organic TFT was found having a field effect mobility of 2.2×10⁻¹ cm²/Vs and an on/off ratio of about 6 digits and thus showing good performances.

### Comparative Example 1

A gate electrode, a gate insulating film, and source and drain electrodes were formed on a substrate in the same manner as Example 1. After that, a pentacene thin film with a thickness of 100 nm was vapor-deposited in a condition of a vacuum degree of 1×10⁻⁶ Torr and a vapor-deposition speed of 10 Å/min to form an organic thin film and accordingly an organic TFT was fabricated.

When the formed organic thin film was observed by an atomic force microscope to confirm the morphology, Φ1 μm of dendrite type grains attributed to the pentacene vapor-deposited film were observed.

Further, the obtained organic thin film transistor was found having a field effect mobility of 1.0×10⁻¹ cm²/Vs and an on/off ratio of about 5 digits.

### Comparative Example 2

A gate electrode, a gate insulating film, and source and drain electrodes were formed on a substrate in the same manner as Example 1. Successively, the obtained substrate was immersed in a mixed solution of hydrogen peroxide and concentrated sulfuric acid (mixing ratio 3:7) for 1 hour to make the surface of the gate insulating film hydrophilic. After that, the obtained substrate was immersed in a 2 mM solution obtained by dissolving octadecyltrichlorosilane (OTS) in a non-aqueous solvent (e.g. n-hexadecane) for 5 minutes in an aerobic condition, slowly pulled out of the solution, and washed with a solvent to form an OTS film. Successively, a pentacene thin film with a thickness of 100 nm was vapor-deposited in a condition of a vacuum degree of 1×10⁻⁶ Torr and a vapor-deposition speed of 10 Å/min to form an organic thin film and accordingly an organic TFT was fabricated.

When the formed organic thin film was observed by an atomic force microscope to confirm the morphology, (2.5 μm of dendrite type grains attributed to the pentacene vapor-deposited film were observed.

Further, the obtained organic thin film transistor was found having a field effect mobility of 1.5×10⁻² cm²/Vs and an on/off ratio of about 5 digits.

### Examples 2 to 18 and Comparative Examples 3 to 9

Organic TFTs were fabricated in the same manner as Example 1, except that the raw materials for the anchor film and organic thin film and formation method of both films were changed as shown in Table 2. The mobility and the on/off ratio of the obtained organic TFTs were measured in the same manner as Example 1 and the results are shown in Table 2.

TABLE 2-1

| | | raw material of | fabrication method of | raw material of | thickness of | fabrication method | | on/off |
|---|---|---|---|---|---|---|---|---|
| | | organic thin film | organic thin film | anchor film | anchor film (nm) | of anchor film | mobility | ratio |
| Ex. | 1 | pentacene | vapor-deposition | (10) | 1.4 | dipping | 2.2 × 10⁻¹ | 6 digits |
| | 2 | pentacene | vapor-deposition | (8) | 0.9 | dipping | 1.6 × 10⁻¹ | 6 digits |
| | 3 | pentacene | vapor-deposition | (9) | 1.2 | dipping | 1.8 × 10⁻¹ | 6 digits |
| | 4 | pentacene | vapor-deposition | (11) | 1.5 | LB method | 2.0 × 10⁻¹ | 6 digits |
| | 5 | naphthacene | vapor-deposition | (10) | 1.4 | CVD method | 3.0 × 10⁻² | 5 digits |
| | 6 | naphthacene | vapor-deposition | (9) | 1.2 | CVD method | 2.0 × 10⁻² | 5 digits |
| | 7 | 1,3,5,8,10,12- | solution coating method | (10) | 1.4 | dipping | 7.2 × 10⁻² | 5 digits |
| | | hexaisopropylepentacene | | | | | | |
| | 8 | α-6T | vapor-deposition | (2) | 1.5 | dipping | 8.5 × 10⁻² | 5 digits |
| | 9 | α-6T | vapor-deposition | (1) | 1.2 | dipping | 6.5 × 10⁻² | 5 digits |
| | 10 | α-6T | vapor-deposition | (4) | 2.1 | LB method | 1.0 × 10⁻¹ | 6 digits |
| | 11 | α-6T | vapor-deposition | (5) | 2.3 | LB method | 1.3 × 10⁻¹ | 6 digits |
| | 12 | rubrene | vapor-deposition | (8) | 1.2 | dipping | 2.4 × 10⁻² | 6 digits |
| | 13 | perylene | vapor-deposition | (9) | 0.9 | dipping | 3 × 10⁻³ (n type) | 5 digits |
| | 14 | perylene | vapor-deposition | (13) | 2.0 | dipping | 4 × 10⁻³ (n type) | 5 digits |
| | 15 | P3HT | solution coating method | (6) | 2.2 | dipping | 2.2 × 10⁻³ | 4 digits |
| | 16 | P3HT | solution coating method | (3) | 1.9 | dipping | 6.1 × 10⁻³ | 4 digits |
| | 17 | PPV | solution coating method | (12) | 1.8 | dipping | 4.2 × 10⁻³ | 3 digits |
| | 18 | PPV | solution coating method | (7) | 2.6 | dipping | 5.8 × 10⁻³ | 3 digits |

TABLE 2-2

| | | raw material of | fabrication method of | raw material of | thickness of | fabrication method | | on/off |
|---|---|---|---|---|---|---|---|---|
| | | organic thin film | organic thin film | anchor film | anchor film (nm) | of anchor film | mobility | ratio |
| Com. Ex. | 1 | pentacene | vapor-deposition | — | | — | 1.0 × 10⁻¹ | 5 digits |
| | 2 | pentacene | vapor-deposition | OTS | 2.1 | dipping | 1.5 × 10⁻¹ | 5 digits |
| | 3 | naphthacene | vapor-deposition | — | | — | 8.3 × 10⁻³ | 4 digits |
| | 4 | α-6T | vapor-deposition | — | | — | 2.1 × 10⁻² | 4 digits |
| | 5 | rubrene | vapor-deposition | — | | — | 1.0 × 10⁻² | 4 digits |
| | 6 | perylene | vapor-deposition | — | | — | 9 × 10⁻⁴ | 3 digits |
| | | | | | | | (n type) | |
| | 7 | 1,3,5,8,10,12- | solution coating method | — | | — | 2.1 × 10⁻² | 4 digits |
| | | hexaisopropylepentacene | | | | | | |
| | 8 | P3HT | solution coating method | — | | — | 9.7 × 10⁻⁴ | 3 digits |
| | 9 | PPV | solution coating method | — | | — | 7.5 × 10⁻⁴ | 2 digits |

The raw materials (1) to (13) for the organic thin films in Table 2 are described below. The production methods of these raw materials will be described collectively as synthesis examples in the last part of Examples. Et denotes ethyl and Me denotes methyl.

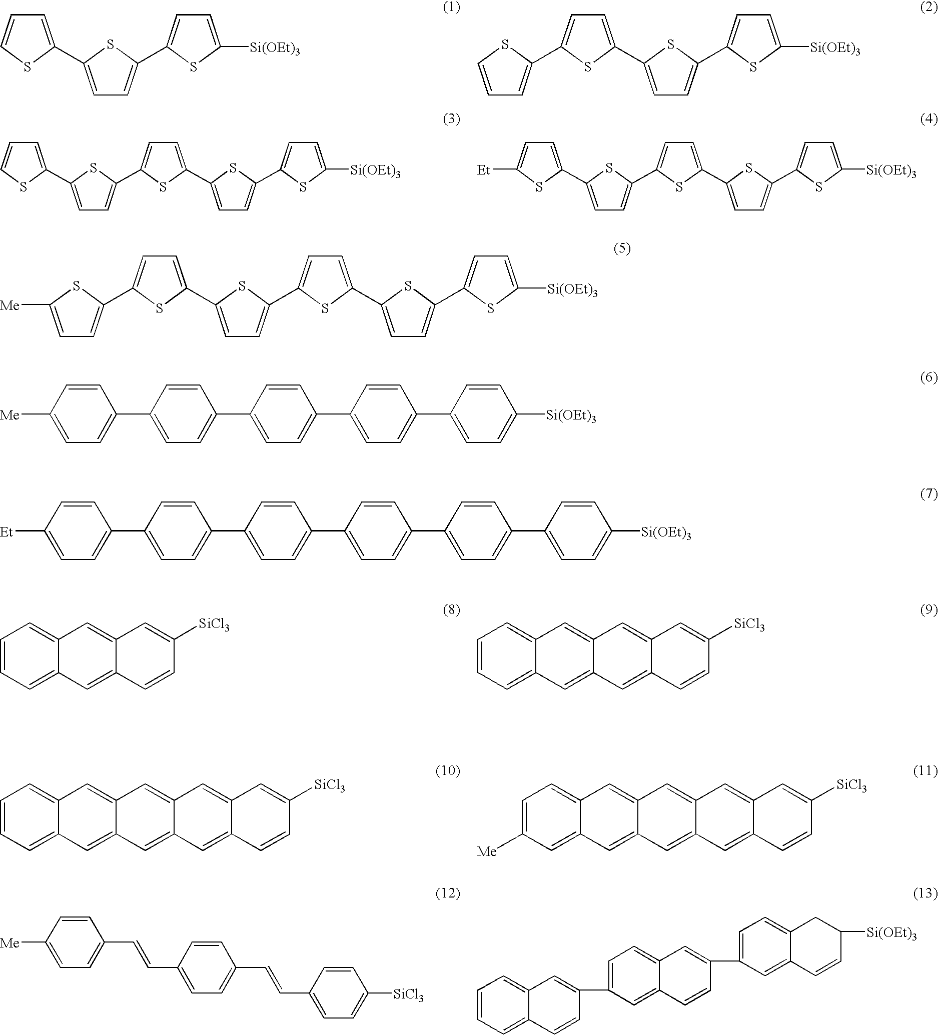

With respect to Examples and Comparative Examples using the same organic thin film shown in Table 2, the improvement ratios of the mobility and on/off ratios of Examples to Comparative Examples using no anchor film are collectively shown in Table 3. Table 3 also shows the improvement ratios of the mobility and on/off ratios of Comparative Example 2 to Comparative Example 1.

TABLE 3

| | improvement ratio | improvement ratio | |
|---|---|---|---|
| | of mobility | of on/off ratio | |
| Ex. 1 to 4/Com. Ex. 1 | 1.6 to 2.2 times | 1 | digit |
| | average 1.9 times | | |
| Ex. 5, 6/Com. Ex. 3 | 2.4 to 3.6 times | 1 | digit |
| | average 3.0 times | | |
| Ex. 7/Com. Ex7 | 3.4 times | 1 | digit |
| Ex. 8 to 11/Com. Ex. 4 | 3.1 to 6.2 times | 1 to 2 | digits |
| | average 4.5 times | | |
| Ex. 12/Com. Ex. 5 | 2.4 times | 2 | digits |
| Ex. 13, 14/Com. Ex. 6 | 3.3 to 4.4 times | 2 | digits |
| | average 3.9 times | | |
| Ex. 15, 16/Com. Ex. 8 | 2.3 to 6.3 times | 1 | digit |
| | average 4.3 times | | |
| Ex. 17, 18/Com. Ex. 9 | 5.6 to 7.7 times | 1 | digit |
| | average 6.7 times | | |

| | | |
|---|---|---|
| Com. Ex. 1/Com. Ex. 2 | 1.5 times | same |

The improvement ratios of the mobility and on/off ratios of Examples to Comparative Examples, which use the same organic thin film and no anchor film shown in Table 2, are shown collectively in Table 4 for respective groups of Examples in which the anchor film was formed in the same method.

TABLE 4

| fabrication method | improvement ratio | improvement ratio | |
|---|---|---|---|
| of anchor film | of mobility | of on/off ratio | |
| dipping | 1.6 to 7.7 times | 1 to 2 | digits |
| (Ex. 1 to 3, 7 to 9, 12 to 18) | average 3.7 times | | |
| CVD method (Ex. 5.6) | 2.4 to 3.6 times | 1 | digit |
| | average 3.0 times | | |
| LB method (Ex. 4, 10, 11) | 2.0 to 6.2 times | 2 | digits |
| | average 4.3 times | | |

The improvement ratios of the mobility and on/off ratios of Examples to Comparative Examples, which use the same organic thin film and no anchor film shown in Table 2, are shown collectively in Table 5 for respective groups of Examples in which the organic thin film was formed in the same method (only Examples in which the anchor film formation method was the immersion method).

TABLE 5

| fabrication method of | improvement ratio | improvement ratio | |
|---|---|---|---|
| organic thin film | of mobility | of on/off ratio | |
| solution coating method | 2.3 to 7.7 times | 1 | digit |
| (Ex. 7, 15 to 18) | average 5.1 times | | |
| vapor-deposition | 1.8 to 4.4 times | 1 to 2 | digits |
| (Ex. 1 to 3, 8, 9, 12 to 14) | average 2.9 times | | |

From Tables 2 to 5, based on comparison of Examples and Comparative Examples, it is found that in the case the anchor film having the carrier transportation function is inserted, the device properties (mobility and on/off ratio) are improved and the grain size of the organic thin film can be enlarged.

More particularly, from Table 3, the mobility of the organic TFT of Comparative Example 2 comprising the monomolecular film of OTS having no carrier transportation function as an anchor film is found 1.5 times as high as that of the organic TFT of Comparative Example 1 comprising no anchor film. On the contrary, the mobility of the organic TFTs of Examples was on the average 1.9 to 6.7 times as high as that of the organic TFT of Comparative Example 1. Accordingly, it is found that the effect of improving the device properties is high in the organic TFTs of Examples comprising the monomolecular film having the carrier transportation function as an anchor layer, regardless of the type of the organic thin film.

Further, from Table 4, it is found that the mobility and on/off ratio are improved more by the CVD method, immersion method, and LB method in this order as the anchor film formation method. In consideration of mass production, it may be said that since the immersion method is simple in the production process and shortens the time taken for the production as compared with the LB method, this method is the most preferable method.

Further, from Table 5, better results are obtained in the case of the solution application method (5.1 times as high on the average) for the organic thin film formation as compared with the results in the case of the vapor-deposition method (2.9 times as high on the average). In addition, the solution application method is effective for obtaining the organic thin film more simply than the vapor-deposition method. Accordingly, it may be said that the solution application method is the most preferable means as the organic thin film formation method.

(Confirmation of Work Function)

### Example 19

First, a thin film of copper is formed on a silicon substrate by sputtering and successively, the obtained substrate was immersed in a mixed solution of hydrogen peroxide and concentrated sulfuric acid (mixing ratio 3:7) for 1 hour to carry out hydrophilicity improvement treatment. After that, the obtained substrate was immersed in a 20 mM solution obtained by dissolving naphthacene-triethoxysilane in a non-aqueous solvent (e.g. n-hexadecane) for 5 minutes in an aerobic condition, slowly pulled out of the solution, and washed with a solvent to form a buffer film. When the work function of the substrate obtained in the above-mentioned manner was measured by the Kelvin method, it was 5.1 eV.

### Examples 20 to 30

Substrate/copper/buffer film systems were obtained in the same manner as Example 19, except the raw materials for the buffer film were changed as shown in Table 6. The work function of each of the obtained systems was measured in the same manner as Example 19 and the results are shown in Table 6.

TABLE 6

| | | work |
|---|---|---|
| | | function |
| Ex. | raw material of buffer film | (eV) |
| 19 | naphthacene-triethoxysilane | 5.1 |
| 20 | anthracene-triethoxysilane | 5.7 |
| 21 | pentacene-triethoxysilane | 4.9 |
| 22 | hexacene-triethoxysilane | 4.6 |
| 23 | quaterthiophenetrichlorosilane | 6.1 |
| 24 | quinquethiophenetriethoxysilane | 5.5 |
| 25 | 2-methylsexi-thiophenetrimethoxysilane | 5.0 |
| 26 | 2-methylheptathiophene-trimethoxysilane | 4.8 |
| 27 | 2-methyloctathiophene-trimethoxysilane | 4.6 |
| 28 | materials of Ex. 20 + Ex. 21 (1:1) | 5.0 |
| 29 | materials of Ex. 23 + 24 + 25 (1:1:1) | 5.5 |
| 30 | materials of Ex. 25 + 26 + 27 (1:1:1) | 4.8 |

The production methods of these raw materials of the buffer films in Table 6 will be described collectively as synthesis examples in the last part of Examples. In this connection, the raw materials used for Examples 21 and 24 are the same as the compounds (10) and (3), which are the raw materials of an anchor film, so that their synthesis methods are omitted.

(TFT Fabrication and Property Confirmation)

### Example 31

To fabricate an organic TFT shown in FIG. 3, an ethanol solution in which 20% by weight of silver is dispersed was applied to a silicon substrate 1 and the substrate was fired at 300° C. for 1 hour to form a gate electrode 2.

Next, after a gate insulating film 3, which was a silicon nitride film, was deposited by the plasma CVD method, again the ethanol solution in which 20% by weight of silver is dispersed was applied to the substrate and the substrate was fired at 300° C. for 1 hour to form source/drain electrodes (5, 7) (work function 4.3 eV)

Successively, the obtained substrate was immersed in a mixed solution of hydrogen peroxide and concentrated sulfuric acid (mixing ratio 3:7) for 1 hour to make the surface of the gate insulating film 3 hydrophilic. After that, the obtained substrate was immersed in a 20 mM solution obtained by dissolving naphthacene-triethoxysilane in a non-aqueous solvent (e.g. n-hexadecane) for 5 minutes in an aerobic condition, slowly pulled out of the solution, and washed with a solvent to form a buffer film 41.

Successively, the resulting substrate was introduced into vacuum and a naphthacene thin film with a thickness of 100 nm was vapor-deposited in a condition of a vacuum degree of 1×10⁻⁶ Torr and a vapor-deposition speed of 10 Å/min to form an organic thin film 6 and accordingly an organic TFT was fabricated.

The organic TFT obtained in the above-mentioned manner was found having a field effect mobility of 5.5×10⁻² cm²/Vs and an on/off ratio of about 4 digits and thus showing good performances.

### Example 32

First, a gate electrode, a gate insulating film, and source/drain electrodes were formed on a substrate in the same manner as Example 31 and the obtained substrate was subject to hydrophilicity improvement treatment. After that, the obtained substrate was immersed in a 20 mM solution obtained by dissolving pentacene-triethoxysilane in a non-aqueous solvent (e.g. n-hexadecane) for 5 minutes in an aerobic condition, slowly pulled out of the solution, and washed with a solvent to form a buffer film. Successively, the substrate was introduced into vacuum and a naphthacene thin film with a thickness of 100 nm was vapor-deposited in a condition of a vacuum degree of 1×10⁻⁶ Torr and a vapor-deposition speed of 10 Å/min to form an organic thin film and accordingly an organic TFT was fabricated.

The organic TFT obtained in the above-mentioned manner was found having a field effect mobility of 7.1×10⁻² cm²/Vs and an on/off ratio of about 5 digits and thus showing good performances.

### Example 33

First, a gate electrode, a gate insulating film, and source/drain electrodes were formed on a substrate in the same manner as Example 31 and the obtained substrate was subject to hydrophilicity improvement treatment. After that, the obtained substrate was immersed in a solution obtained by dissolving 10 mM of naphthacene-triethoxysilane and 10 mM of pentacene-triethoxysilane in a non-aqueous solvent (e.g. n-hexadecane) for 5 minutes in an aerobic condition, slowly pulled out of the solution, and washed with a solvent to form a buffer film. Successively the substrate was introduced into vacuum and a naphthacene thin film with a thickness of 100 nm was vapor-deposited in a condition of a vacuum degree of 1×10⁻⁶ Torr and a vapor-deposition speed of 10 Å/min to form an organic thin film and accordingly an organic TFT was fabricated.

The organic TFT obtained in the above-mentioned manner was found having a field effect mobility of 8.5×10⁻² cm²/Vs and an on/off ratio of about 5 digits and thus showing good performances.

### Comparative Example 10

A gate electrode, a gate insulating film, and source/drain electrodes were formed on a substrate in the same manner as Example 31. After that, a naphthacene thin film with a thickness of 100 nm was vapor-deposited in a condition of a vacuum degree of 1×10⁻⁶ Torr and a vapor-deposition speed of 10 Å/min to form an organic thin film and accordingly an organic TFT was fabricated.

The organic thin film transistor obtained in the above-mentioned manner was found having a field effect mobility of 8.3×10⁻³ cm²/Vs and an on/off ratio of about 3 digits.

Comparing Comparative Example 10 with Example 31, as shown in the case of Example 31, it can be confirmed that the higher properties can be obtained if the buffer film is formed. Accordingly, it is found that intermediation of the buffer film efficiently improves the carrier transportation from the electrodes to the organic thin film.

Comparing Example 31 with Example 32, if the buffer film having a work function between the organic thin film (naphthacene in Examples) and electrodes (source/drain electrodes in Examples) is contained, further improved properties can be obtained.

Further, it is also confirmed that although the material for Example 33 has a lower work function than that of the material for Example 32, the properties of the system of Example 33 are better. It is supposed because in Example 33, the buffer film is of a mixture of naphthacene-triethoxysilane and pentacene-triethoxysilane and although the work function is apparently a middle value of the work functions of the above-mentioned two kinds of compounds, the carriers in the thin film are transported from the electrode to pentacene-triethoxysilane, naphthacene-triethoxysilane, and naphthacene in this order. As described above, use of a mixed system for the buffer film makes it possible to obtain an organic TFT with further improved properties.

### Example 34

First, tantalum was vapor-deposited on a silicone substrate to form a gate electrode.

Next, after a gate insulating film, which was a silicon nitride film, was deposited by a plasma CVD method, a thin film of copper (work function 4.7 eV) was formed by sputtering and source/drain electrodes were formed by a common lithographic technique.

Successively, the obtained substrate was immersed in a mixed solution of hydrogen peroxide and concentrated sulfuric acid (mixing ratio 3:7) for 1 hour to make the surface of the gate insulating film hydrophilic as shown the case of Example 1. After that, the obtained substrate was immersed in a solution obtained by dissolving 20 mM of anthracene-triethoxysilane in a non-aqueous solvent (e.g. n-hexadecane) for 5 minutes in an aerobic condition, slowly pulled out of the solution, and washed with a solvent to form a buffer film.

After that, an anthracene thin film with a thickness of 100 nm was vapor-deposited in a condition of a vacuum degree of 1×10⁻⁶ Torr and a vapor-deposition speed of 10 Å/min to form an organic thin film and accordingly an organic TFT was fabricated.

The organic TFT obtained in the above-mentioned manner was found having a field effect mobility of 8.5×10⁻⁴ cm²/Vs and an on/off ratio of about 4 digits.

### Examples 35 to 40 and Comparative Examples 11 to 17

Organic TFTs were fabricated in the same manner as Example 31, except that the raw materials for the electrode, buffer film and organic thin film and formation method of both films were changed as shown in Table 7. The mobility and the on/off ratio of the obtained organic TFTs were measured in the same manner as Example 31 and the results are shown in Table 7.

TABLE 7

| | | raw material | | | | | | |
|---|---|---|---|---|---|---|---|---|
| | | of electrode | organic thin film | fabrication method | buffer film | fabrication method | mobility (cm²/Vs) | on/off ratio (digit) |
| Ex. | 31 | Ag | naphthacene | vapor-deposition | P4 | dipping | 5.5 × 10⁻² | 4 |
| | 32 | Ag | naphthacene | vapor-deposition | P5 | dipping | 7.1 × 10⁻² | 5 |
| | 33 | Ag | naphthacene | vapor-deposition | P4 + P5(1:1) | dipping | 8.5 × 10⁻² | 5 |
| | 34 | Cu | anthracene | vapor-deposition | P3 | dipping | 8.5 × 10⁻⁴ | 4 |
| | 35 | Ag | pentacene | vapor-deposition | P6 | LB | 2.5 × 10⁻¹ | 5 |
| | 36 | Ag | hp naphthacene | solution coating method | P5 | dipping | 4 × 10⁻² | 5 |
| | 37 | Ag | dp pentacene | solution coating method | P6 | LB | 9.6 × 10⁻² | 5 |
| | 38 | Cu | α-6T | vapor-deposition | 6T/7T/8T | LB | 1.7 × 10⁻¹ | 5 |
| | 39 | Cu | quinquethiophene | vapor-deposition | 6T | dipping | 1.5 × 10⁻² | 4 |
| | 40 | Cu | quaterthiophene | vapor-deposition | 4T/5T/6T | dipping | 2.5 × 10⁻³ | 4 |
| Com. Ex. | 10 | Ag | naphthacene | vapor-deposition | — | — | 8.3 × 10⁻³ | 4 |
| | 11 | Ag | hp naphthacene | solution coating method | — | — | 4.5 × 10⁻² | 4 |
| | 12 | Cu | anthracene | vapor-deposition | — | — | 5.2 × 10⁻⁴ | 3 |
| | 13 | Ag | dp pentacene | solution coating method | — | — | 2.1 × 10⁻² | 4 |
| | 14 | Ag | pentacene | vapor-deposition | — | — | 1.0 × 10⁻¹ | 5 |
| | 15 | Cu | α-6T | vapor-deposition | — | — | 2.1 × 10⁻² | 4 |
| | 16 | Cu | quinquethiophene | vapor-deposition | — | — | 6.5 × 10⁻¹ | 3 |
| | 17 | Cu | quaterthiophene | vapor-deposition | — | — | 4.1 × 10⁻⁴ | 3 |

In Table 7, P3 denotes naphthacene-triethoxysilane; P4 anthracene-triethoxysilane; P5 pentacene-triethoxysilane; P6 hexacene-triethoxysilane; 4T quarterthiophenetrichlorosilane; 5T quinquethiophene-trimethoxysilane; 6T 2-methylsextet-thiophene-trimethoxysilane; 7T 2-methylheptathiophene-trimethoxysilane; and 8T 2-methyloctathiophene-trimethoxysilane.

Comparing Examples 34 to 40 with Comparative Examples 11 to 17, respectively, similarly to the relation between Examples 31 to 33 and Comparative Example 10, it is confirmed that the properties are improved in a system having no buffer film, a system containing a buffer film having a work function approximately the same as that of an organic thin film, a system containing a buffer film having a work function of a middle value between an organic thin film and an electrode, and a mixture system containing a plurality of buffer films having a work function of a middle value between an organic thin film and an electrode in this order. That is, the following is confirmed: that if the buffer film is used, the organic TFT having good properties is obtained; that if the buffer film has a work function of a middle value between an organic thin film and an electrode, further improved properties can be obtained; and that if the buffer film is a mixture system containing a plurality of materials having a work function of a middle value between an organic thin film and an electrode, even further improved properties can be obtained.

### Synthesis Example 1

### Synthesis of terthiophenetrichlorosilane by Grignard Method

### (Starting Material (1))

After 1.0 mole of terthiophene was dissolved in carbon tetrachloride in a 500 ml glass flask equipped with a stirrer, a refluxing condenser, a thermometer, and a titration funnel, NBS and AIBN were added and stirred for 2.5 hours and the reaction product was filtered under reduced pressure to obtain bromoterthiophene. Successively, 0.5 mole of metal magnesium and 300 ml of THF (tetrahydrofuran) were loaded to a 500 ml glass flask equipped with a stirrer, a refluxing condenser, a thermometer, and a titration funnel, and 0.5 mole of the above-mentioned bromoterthiophene was dropwise added at 50 to 60° C. through the titration funnel over 2 hours and on completion of the titration, aging was carried out at 65° C. for 2 hours to produce Grignard reagent. A 1 l glass flask equipped with a stirrer, a refluxing condenser, a thermometer, and a titration funnel was loaded with 1.5 mole of SiCl₄ (tetrachlorosilane) and 300 ml of toluene and cooled with ice and the above-mentioned Grignard reagent was added over 2 hours at an inner temperature of 20° C. or lower and on completion of titration, aging was carried out at 30° C. for 1 hour (Grignard reaction).

Next, after the reaction solution was filtered under reduced pressure to remove magnesium chloride, toluene and unreacted tetrachlorosilane were stripped from the obtained filtrate and the resulting solution was distilled to obtain the title compound at 55% yield.

The obtained compound was subjected to IR absorption spectrometry to find that absorption attributed to SiC was observed at 1060 cm⁻¹ and accordingly the compound had an SiC bond.

Further, when a solution containing the compound was subjected to ultraviolet to visible absorption spectrometry, absorption at wavelength of 360 nm was observed. The absorption is attributed to π→π*transition of the terthiophene molecule contained in the molecule to prove that the compound contained a terthiophene molecule.

Further, the compound was subjected to nuclear magnetic resonance (NMR) measurement. Since the compound has high reactivity, it was impossible to carry out direct NMR measurement of the compound and therefore the compound was reacted with ethanol (generation of hydrogen chloride was confirmed) to replace chlorine at the terminal with an ethoxy group and then the measurement was carried out.

7.50 ppm to 7.00 ppm (m) (7H derived from thiophene ring)

2.20 ppm (m) (3H derived from ethoxy group)

Based on these results, the compound was confirmed to be terthiophenetrichlorosilane defined by the formula (2).

### Synthesis Example 2

### Synthesis of quaterthiophenetrichlorosilane

### (Starting Material (2))

After 1.0 mole of quaterthiophene was dissolved in carbon tetrachloride in a 500 ml glass flask equipped with a stirrer, a refluxing condenser, a thermometer, and a titration funnel, NBS and AIBN were added and stirred for 2.5 hours and the reaction product was filtered under reduced pressure to obtain bromoquaterthiophene. Successively, 0.5 mole of metal magnesium and 300 ml of THF (tetrahydrofuran) were loaded to a 500 ml glass flask equipped with a stirrer, a refluxing condenser, a thermometer, and a titration funnel, and 0.5 mole of the above-mentioned bromoquaterthiophene was dropwise added at 50 to 60° C. through the titration funnel over 2 hours and on completion of the titration, aging was carried out at 65° C. for 2 hours to produce Grignard reagent. A 1 l glass flask equipped with a stirrer, a refluxing condenser, a thermometer, and a titration funnel was loaded with 1.5 mole of SiCl₄ (tetrachlorosilane) and 300 ml of toluene and cooled with ice and the above-mentioned Grignard reagent was dropwise added over 2 hours at an inner temperature of 20° C. or lower and on completion of titration, aging was carried out at 30° C. for 1 hour.

Next, after the reaction solution was filtered under reduced pressure to remove magnesium chloride, toluene and unreacted tetrachlorosilane were stripped from the obtained filtrate and the resulting solution was distilled to obtain the title compound at 45% yield.

The obtained compound was subjected to IR absorption spectrometry to find that absorption attributed to SiC was observed at 1060 cm⁻¹ and accordingly the compound had an SiC bond.

Further, when a solution containing the compound was subjected to ultraviolet to visible absorption spectrometry, absorption at wavelength of 390 nm was observed. Further, the compound was subjected to nuclear magnetic resonance (NMR) measurement. Since the compound has high reactivity, it was impossible to carry out direct NMR measurement of the compound and therefore the compound was reacted with ethanol (generation of hydrogen chloride was confirmed) to replace chlorine at the terminal with an ethoxy group and then the measurement was carried out.

7.30 ppm (m) (1H derived from thiophene ring)

7.20 ppm to 7.00 ppm (m) (8H derived from thiophene ring)

2.20 ppm (m) (3H derived from ethoxy group)

Based on these results, the compound was confirmed to be a quaterthiophenetrichlorosilane.

### Synthesis Example 3

### Synthesis of quinquethiophenetrichlorosilane

### (Starting Material (3))

After 1.0 mole of bithiophene was dissolved in carbon tetrachloride in a 500 ml glass flask equipped with a stirrer, a refluxing condenser, a thermometer, and a titration funnel, NBS and AIBN were added and stirred for 2.5 hours and the reaction product was filtered under reduced pressure to obtain bromobithiophene. Successively, 0.5 mole of bromoterthiophene, which was an intermediate of Synthesis Example 1, was synthesized and 0.5 mole of metal magnesium and 300 ml of THF (tetrahydrofuran) were loaded to a 500 ml glass flask equipped with a stirrer, a refluxing condenser, a thermometer, and a titration funnel, and 0.5 mole of the above-mentioned bromoterthiophene was dropwise added at 50 to 60° C. through the titration funnel over 2 hours and on completion of the titration, aging was carried out at 65° C. for 2 hours to produce Grignard reagent. Further, 0.5 mole of the above-mentioned bromobithiophene was added and reaction was carried out at 50° C. for 4 hours to synthesize quinquethiophene. Successively, after 0.2 mole of the quinquethiophene was reacted with NBS in the presence of AIBN to synthesize bromoquinquethiophene, reaction with metal magnesium was carried out to synthesize Grignard reagent. Further, a 1 l glass flask equipped with a stirrer, a refluxing condenser, a thermometer, and a titration funnel was loaded with 1.5 mole of triethoxychlorosilane and 300 ml of toluene and cooled with ice and the above-mentioned Grignard reagent was dropwise added over 2 hours at an inner temperature of 20° C. or lower and on completion of titration, aging was carried out at 30° C. for 1 hour.

Next, after the reaction solution was filtered under reduced pressure to remove magnesium chloride, toluene and unreacted substances were stripped from the obtained filtrate and the resulting solution was distilled to obtain the title compound at 45% yield.

The obtained compound was subjected to IR absorption spectrometry to find that absorption attributed to SiC was observed at 1050 cm⁻¹ and accordingly the compound had an SiC bond.

Further, the compound was subjected to nuclear magnetic resonance (NMR) measurement.

7.3 ppm (m) (2H derived from thiophene ring)

6.6 ppm (m) (8H derived from thiophene ring)

3.8 ppm (m) (6H derived from methylene of ethoxy group)

1.2 ppm (m) (9H derived from methyl of ethoxy group)

Based on these results, the compound was confirmed to be the title compound.

### Synthesis Example 4

### Synthesis of 2-ethylquinquethiophenetriethoxysilane

### (Starting Material (4))

After 1.0 mole of 2-ethylbithiophene was dissolved in carbon tetrachloride in a 500 ml glass flask equipped with a stirrer, a refluxing condenser, a thermometer, and a titration funnel, NBS and AIBN were added and stirred for 2.5 hours, and the reaction product was filtered under reduced pressure to obtain 2-ethyl-5″-bromobithiophene.

Successively, 0.5 mole of bromoterthiophene, which was an intermediate of Synthesis Example 1, was synthesized and 0.5 mole of metal magnesium and 300 ml of THF (tetrahydrofuran) were loaded to a 500 ml glass flask equipped with a stirrer, a refluxing condenser, a thermometer, and a titration funnel, and 0.5 mole of the above-mentioned bromoterthiophene was dropwise added at 50 to 60° C. through the titration funnel over 2 hours and on completion of the titration, aging was carried out at 65° C. for 2 hours to produce Grignard reagent. Further, 0.5 mole of the above-mentioned 2-ethyl-5″-bromobithiophene was added and reaction was carried out at 50° C. for 4 hours to synthesize 2-ethylquinquethiophene. Successively, after 0.2 mole of the quinquethiophene was reacted with NBS in the presence of AIBN to synthesize 2-ethyl-5″″′-bromoquinquethiophene, reaction with metal magnesium was carried out to synthesize Grignard reagent. Further, a 1 l glass flask equipped with a stirrer, a refluxing condenser, a thermometer, and a titration funnel was loaded with 1.5 mole of triethoxychlorosilane and 300 ml of toluene and cooled with ice and the above-mentioned Grignard reagent was added over 2 hours at an inner temperature of 20° C. or lower and on completion of titration, aging was carried out at 30° C. for 1 hour.

Next, after the reaction solution was filtered under reduced pressure to remove magnesium chloride, toluene and unreacted substances were stripped from the obtained filtrate and the resulting solution was distilled to obtain the title compound at 45% yield.

The obtained compound was subjected to IR absorption spectrometry to find that absorption attributed to SiC was observed at 1050 cm⁻¹ and accordingly the compound had an SiC bond.

Further, the compound was subjected to nuclear magnetic resonance (NMR) measurement.

7.3 ppm (m) (2H derived from thiophene ring)

7.2 ppm (m) (8H derived from thiophene ring)

3.8 ppm (m) (2H derived from methylene group of ethyl group)

3.5 ppm (m) (6H derived from methylene of ethoxy group)

2.6 ppm (m) (3H derived from methyl group of ethyl group)

1.2 ppm (m) (9H derived from methyl group of ethoxy group)

Based on these results, the compound was confirmed to be the title compound.

### Synthesis Example 5

### Synthesis of 2-methylsexi-thiophenetrimethoxysilane

### (Starting Material (5))

First, 1.5 mole of bromoterthiophene, which was an intermediate of Synthesis Example 1, was synthesized. Successively, methylterthiophene was synthesized by reaction of 1.0 mole of the above-mentioned bromoterthiphene and 1.0 mole of bromomethane at 60° C. for 3 hours. Next, 0.7 mole of the above-mentioned methylterthiphene was reacted with NBS in the presence of AIBN to synthesize 2-ethyl-5″-bromoterthiophene.

On the other hand, 0.5 mole of metal magnesium and 300 ml of THF (tetrahydrofuran) were loaded to a 500 ml glass flask equipped with a stirrer, a refluxing condenser, a thermometer, and a titration funnel and 0.5 mole of the above-mentioned bromoterthiophene was dropwise added through the titration funnel at 50 to 60° C. over 2 hours and on completion of the titration, aging was carried out at 65° C. for 2 hours to produce Grignard reagent.

Successively, the above-mentioned 2-methyl-5-bromoterthiophene was further added and reaction was carried out at 60° C. for 4 hours to synthesize 2-methylsexi-thiophene. Further, after 0.2 mole of the above-mentioned 2-methylsexi-thiophene was reacted with NBS in the presence of AIBN to synthesize 2-ethyl-5″″′-bromosexi-thiophene, reaction with metal magnesium was carried out to obtain Grignard reagent. Further, a 1 l glass flask equipped with a stirrer, a refluxing condenser, a thermometer, and a titration funnel was loaded with 1.5 mole of triethoxychlorosilane and 300 ml of toluene and cooled with ice and the above-mentioned Grignard reagent was added over 2 hours at an inner temperature of 20° C. or lower and on completion of titration, aging was carried out at 30° C. for 1 hour.

Next, after the reaction solution was filtered under reduced pressure to remove magnesium chloride, toluene and unreacted substances were stripped from the obtained filtrate and the resulting solution was distilled to obtain the title compound.

The obtained compound was subjected to IR absorption spectrometry to find that absorption attributed to SiC was observed at 1050 cm⁻¹ and accordingly the compound had an SiC bond.

Further, the compound was subjected to nuclear magnetic resonance (NMR) measurement.

7.3 ppm (m) (2H derived from thiophene ring)

7.1 ppm (m) (10H derived from thiophene ring)

3.8 ppm (m) (6H derived from methylene of ethoxy group)

2.6 ppm (m) (3H derived from methyl group)

1.2 ppm (m) (9H derived from methyl group of ethoxy group)

Based on these results, the compound was confirmed to be the title compound.

### Synthesis Example 6

### Synthesis of quinquephenyltrichlorosilane

### (Starting Material (6))

A 500 ml glass flask equipped with a stirrer, a refluxing condenser, a thermometer, and a titration funnel was loaded with 0.5 mole of metal magnesium and 300 ml of THF (tetrahydrofuran), and 0.5 mole of quinquephenyl was dropwise added through the titration funnel at 50 to 60 over 2 hours and on completion of the titration, aging was carried out at 65 for 2 hours to synthesize Grignard reagent.

A 1 l glass flask equipped with a stirrer, a refluxing condenser, a thermometer, and a titration funnel was loaded with 1.0 mole of SiCl₄ (tetrachlorosilane) and 300 ml of toluene and cooled with ice and the Grignard reagent was added over 2 hours at an inner temperature of 20 or lower and on completion of titration, aging was carried out at 30 for 1 hour (Grignard reaction).

Next, after the reaction solution was filtered under reduced pressure to remove magnesium chloride, toluene and unreacted tetrachlorosilane were stripped from the obtained filtrate and the resulting solution was distilled to obtain the title compound at 50% yield.

The obtained compound was subjected to IR absorption spectrometry to find that absorption attributed to SiC was observed at 1080 cm⁻¹ and accordingly the compound had an SiC bond.

Further, the compound was subjected to nuclear magnetic resonance (NMR) measurement. Since the compound has high reactivity, it was impossible to carry out direct NMR measurement of the compound and therefore the compound was reacted with ethanol (generation of hydrogen chloride was confirmed) to replace chlorine at the terminal with an ethoxy group and then the measurement was carried out.

7.95 ppm to 7.35 ppm (m) (21H derived from aromatic group)

3.6 ppm (m) (6H derived from methylene group of ethoxy group)

1.4 ppm (m) (9H derived from methyl group of ethoxy group)

Based on these results, the compound was confirmed to be the title compound.

### Synthesis Example 7

### Synthesis of sexi-phenyltrichlorosilane

### (Starting Material (7))

A 500 ml glass flask equipped with a stirrer, a refluxing condenser, a thermometer, and a titration funnel was loaded with 0.5 mole of metal magnesium and 300 ml of THF (tetrahydrofuran), and 0.5 mole of sexi-phenyl was dropwise added through the titration funnel at 50 to 60 over 2 hours and on completion of the titration, aging was carried out at 65 for 2 hours to synthesize Grignard reagent.

A 1 l glass flask equipped with a stirrer, a refluxing condenser, a thermometer, and a titration funnel was loaded with 1.0 mole of SiCl₄ (tetrachlorosilane) and 300 ml of toluene and cooled with ice and the Grignard reagent was added over 2 hours at an inner temperature of 20 or lower and on completion of titration, aging was carried out at 30 for 1 hour (Grignard reaction).

Next, after the reaction solution was filtered under reduced pressure to remove magnesium chloride, toluene and unreacted tetrachlorosilane were stripped from the obtained filtrate and the resulting solution was distilled to obtain the title compound at 45% yield.

The obtained compound was subjected to IR absorption spectrometry to find that absorption attributed to SiC was observed at 1070 cm⁻¹ and accordingly the compound had an SiC bond.

Further, the compound was subjected to nuclear magnetic resonance (NMR) measurement. Since the compound has high reactivity, it was impossible to carry out direct NMR measurement of the compound and therefore the compound was reacted with ethanol (generation of hydrogen chloride acid was confirmed) to replace chlorine at the terminal with an ethoxy group and then the measurement was carried out.

7.95 ppm to 7.35 ppm (m) (25H derived from aromatic group)

3.6 ppm (m) (6H derived from methylene group of ethoxy group)

1.4 ppm (m) (9H derived from methyl group of ethoxy group)

Based on these results, the compound was confirmed to be the title compound.

### Synthesis Example 8

### Synthesis of triethoxysilanylanthracene

### (Starting Material (8))

Triethoxysilanylanthracene was synthesized in the following manner. First, 1 mM of anthracene dissolved in 50 mL of carbon tetrachloride and NBS were added to a 100 ml eggplant flask equipped with a stirrer, a refluxing condenser, a thermometer, and a titration funnel and in the presence of AIBN, reaction was carried out for 1.5 hours. After unreacted substances and HBr were removed by filtration, a stored compound brominated at one position was taken out by column chromatography to obtain 9-bromoanthracene. Successively, reaction with metal magnesium was carried out to obtain Grignard reagent and successively, Grignard reagent was dissolved in a carbon tetrachloride solution containing chloroethoxysilane and reacted at 60° C. for 2 hours to obtain the title compound (yield 15%).

The obtained compound was subjected to IR absorption spectrometry to find that absorption attributed to Si—O—C was observed at 1050 nm and accordingly the compound had a silyl group. Further, the compound was subjected to nuclear magnetic resonance (NMR) measurement.

7.80 ppm to 7.60 ppm (m) (9H derived from aromatic group)

3.8 ppm (m) (6H derived from methylene group of ethoxy group)

1.5 ppm (m) (9H derived from methyl group of ethoxy group)

Based on these results, the compound was confirmed to be the title compound.

### Synthesis Example 9

### Synthesis of triethoxysilanyltetracene

### (Starting Material (9))

Triethoxysilanyltetracene was synthesized in the following manner. First, 1 mM of tetracene dissolved in 50 mL of carbon tetrachloride and NBS were added to a 100 ml eggplant flask equipped with a stirrer, a refluxing condenser, a thermometer, and a titration funnel and in the presence of AIBN, reaction was carried out for 1.5 hours. After unreacted substances and HBr were removed by filtration, a stored compound brominated at one position was taken out by column chromatography to obtain 9-bromotetracene. Successively, reaction with metal magnesium was carried out to obtain Grignard reagent and successively, Grignard reagent was dissolved in a chloroform solution containing H—Si(OC₂H₅)₃ and reacted at 60° C. for 2 hours to obtain the title compound (yield 10%).

The obtained compound was subjected to IR absorption spectrometry to find that absorption attributed to Si—O—C was observed at 1050 nm and accordingly the compound had a silyl group. Further, when a chloroform solution containing the compound was subjected to ultraviolet to visible absorption spectrometry, absorption at wavelength of 481 nm was observed. The absorption is attributed to π→π* transition of the tetracene skeleton contained in the molecule to prove that the compound contained a tetracene skeleton.

Further, the compound was subjected to nuclear magnetic resonance (NMR) measurement.

7.80 ppm to 7.30 ppm (m) (11H derived from aromatic group)

3.6 ppm (m) (6H derived from methylene group of ethoxy group)

1.4 ppm (m) (9H derived from methyl group of ethoxy group)

Based on these results, the compound was confirmed to be the title compound.

### Synthesis Example 10

### Synthesis of triethoxysilanylpentacene

### (Starting Material (10))

Triethoxysilanylpentacene was synthesized in the following manner. First, 1 mM of pentacene dissolved in 50 mL of carbon tetrachloride and NBS were added to a 100 ml eggplant flask equipped with a stirrer, a refluxing condenser, a thermometer, and a titration funnel and in the presence of AIBN, reaction was carried out for 1.5 hours. After unreacted substances and HBr were removed by filtration, a stored compound brominated at one position was taken out by column chromatography to obtain 9-bromopentacene. Successively, reaction with metal magnesium was carried out to obtain Grignard reagent and successively, Grignard reagent was dissolved in a chloroform solution containing H—Si(OC₂H₅)₃ and reacted at 60° C. for 2 hours to obtain the title compound (yield 10%).

The obtained compound was subjected to IR absorption spectrometry to find that absorption attributed to Si—O—C was observed at 1050 nm and accordingly the compound had a silyl group.

Further, the compound was subjected to nuclear magnetic resonance (NMR) measurement.

7.80 ppm to 7.30 ppm (m) (13H derived from aromatic group)

3.6 ppm (m) (6H derived from methylene group of ethoxy group)

1.4 ppm (m) (9H derived from methyl group of ethoxy group)

Based on these results, the compound was confirmed to be the title compound.

### Synthesis Example 11

### Synthesis of 2-methyl10-triethoxysilanylpentacene

### (Starting Material (11))

2-Methyl10-triethoxysilanylpentacene was synthesized in the following manner. First, Grignard reagent was produced by adding magnesium to, for example, a chloroform solution containing bromomethane. Successively, a chloroform solution containing 10-bromopentacene of Synthesis Example 1 was added slowly to synthesize 10-methylpentacene. Successively, the above-mentioned intermediate was brominated using, for example, NBS and compounds brominated at positions other than 2-position were removed by extraction to obtain 2-bromo-10-methylpentacene. Further, H—Si(OC₂H₅)₃ was dissolved in chloroform and the solution was added to a chloroform solution containing the above-mentioned 3-bromo-9-octadecyltetracene to carry out reaction and synthesize the title compound (yield 12%).

The obtained compound was subjected to IR absorption spectrometry to find that absorption attributed to Si—O—C was observed at 1050 nm and accordingly the compound had a silyl group. Further, the compound was subjected to nuclear magnetic resonance (NMR) measurement.

7.80 ppm to 7.30 ppm (m) (13H derived from aromatic group)

3.6 ppm (m) (6H derived from methylene group of ethoxy group)

2.8 ppm (m) (3H derived from methyl group)

1.4 ppm (m) (9H derived from methyl group of ethoxy group)

Based on these results, the compound was confirmed to be the title compound.

### Synthesis Example 12

### Synthesis of trichloro-(4-{2-[4-(2-p-tolyl-ethyl)-phenyl]-ethyl}phenyl)silane

### (Starting Material (12))

The above-mentioned compound was synthesized in the following manner.

First, α-bromoxylene (50 mM) and triethylphosphite (60 mM) were loaded to a 200 ml eggplant flask and heated to 140° C. while being stirred to promote reaction. Further, the temperature was increased to 180° C. to break the residues of triethylphosphite and thereafter, the reaction mixture was cooled to synthesize 4-(methyl-benzyl)-phosphonic acid. Successively, 10 mM of sodium hydroxide was added to dry DMF in 500 ml glass flask equipped with a stirrer, a thermometer, and a titration funnel in argon atmosphere and the solution temperature was adjusted to 0° C. and thereafter, the above-mentioned 4-(methyl-benzyl)-phosphonic acid (8 mM) and a DMF solution (50 ml) of trans-4-stilbenecarboxylaldehyde (7 mM) were slowly added and stirred for 24 hours to promote reaction. On completion of the reaction, the product was extracted with ethanol to synthesize 4-[(E)-2-[4-{(E)-2-phenylvinyl}-phenyl]-vinyl]-phenylmethane. Further, the compound was dissolved in carbon tetrachloride and then NBS was added and AIBN was added and after the mixture was stirred for 2 hours, the reaction solution was filtered under reduced pressure to synthesize the intermediate 4 defined by the following structural formula:

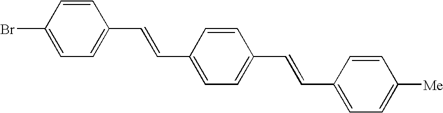

Successively, the intermediate 4 was loaded to a 500 ml glass flask equipped with a stirrer, a refluxing condenser, a thermometer, and a titration funnel, and further 1.0 mole of tetrachlorosilane and 200 ml of toluene were loaded and the mixture was cooled with ice and the intermediate 4 was added over 1 hour at an inner temperature of 10° C. and after titration, aging was carried out for 1 hour to synthesize the compound defined by the above-mentioned structural formula.

When the resulting aimed compound was subjected to IR absorption spectrometry to find that absorption attributed to SiC was observed at 1070 cm⁻¹ and accordingly the compound had an SiC bond. Further, the compound was subjected to nuclear magnetic resonance measurement. Since the compound has high reactivity, it was impossible to carry out direct NMR measurement of the compound and therefore the compound was reacted with ethanol to replace chlorine at the terminal with an ethoxy group and then the measurement was carried out.

7.4 ppm to 7.2 ppm (m) (12H derived from phenyl skeleton)

7.1 ppm to 7.0 ppm (m) (4H derived from vinyl group skeleton)

3.8 ppm to 3.7 ppm (m) (6H derived from methylene of ethoxy group)

2.5 ppm to 2.4 ppm (m) (3H derived from methyl group)

1.4 ppm to 1.2 ppm (m) (9H derived from methyl group of ethoxy group)

Based on these results, the compound was confirmed to be the compound defined by the above-mentioned structural formula.

### Synthesis Example 13

### Synthesis of triethoxy-[2,2′; 6′,2″]ternaphthalen-6-yl-silane

### (Starting Material (13))

First, 100 mM NBS and AIBN were added to 100 mM of a carbon tetrachloride solution containing 50 mM of 2-bromonaphthalene (CAS no. 90-11-9) and reaction was carried out at 60° C. for 2 hours in N₂ atmosphere to synthesize 2,6-dibromonaphthalene. Successively, 40 mM of 2-bromonaphthalene was dissolved in THF and metal magnesium was added and reaction was carried out at 60° C. for 1 hour in N₂ atmosphere to synthesize Grignard reagent. Thereafter, the Grignard reagent was added to a THF solution containing 20 mM of the above-mentioned 2,6-dibromonaphthalene and reaction was carried out at 20° C. for 9 hours to synthesize [2,2′; 6′,2″]ternaphthalene. After that, 20 mM of NBS and AIBN were added to a carbon tetrachloride solution containing 10 mM of the [2,2′; 6′,2″]ternaphthalene and reaction was carried out at 60° C. for 2 hours in N₂ atmosphere to synthesize 6-bromo-[2,2′; 6′,2″]ternaphthalene. Further, metal magnesium was added and reaction was carried out at 60° C. for 1 hour in N₂ atmosphere to synthesize Grignard reagent and further 10 mM of chloroethoxysilane was added and reaction was carried out at 60° C. for 2 hours to obtain the title compound at 40% yield.

The obtained compound was subjected to IR absorption spectrometry to find that absorption attributed to SiC was observed at 1090 cm⁻¹ and accordingly the compound had a SiC bond.

Further, the compound was subjected to nuclear magnetic resonance (NMR) measurement.

7.9 ppm (m) (4H aromatic group)

7.6 ppm (m) (8H aromatic group)

7.5 ppm (m) (4H aromatic group)

7.3 ppm (m) (3H aromatic group)

3.6 ppm (m) (6H methylene group of ethoxy group)

1.5 ppm (m) (9H methyl group of ethoxy group)

Based on these results, the compound was confirmed to be triethoxy-[2,2′; 6′,2″]ternaphthalen-6-yl-silane.

### Synthesis Example 14

### Synthesis of quaterthiophenetrichlorosilane

After 1.0 mole of quaterthiophene was dissolved in carbon tetrachloride in a 500 ml glass flask equipped with a stirrer, a refluxing condenser, a thermometer, and a titration funnel, NBS and AIBN were added and stirred for 2.5 hours and the reaction product was filtered under reduced pressure to obtain bromoquaterthiophene. Successively, 0.5 mole of metal magnesium and 300 ml of THF (tetrahydrofuran) were loaded to a 500 ml glass flask equipped with a stirrer, a refluxing condenser, a thermometer, and a titration funnel, and 0.5 mole of the above-mentioned bromoquaterthiophene was dropwise added at 50 to 60° C. through the titration funnel over 2 hours and on completion of the titration, aging was carried out at 65° C. for 2 hours to produce Grignard reagent. A 1 l glass flask equipped with a stirrer, a refluxing condenser, a thermometer, and a titration funnel was loaded with 1.5 mole of SiCl₄ (tetrachlorosilane) and 300 ml of toluene and cooled with ice and the above-mentioned Grignard reagent was dropwise added over 2 hours at an inner temperature of 20° C. or lower and on completion of titration, aging was carried out at 30° C. for 1 hour.

Next, after the reaction solution was filtered under reduced pressure to remove magnesium chloride, toluene and unreacted tetrachlorosilane were stripped from the obtained filtrate and the resulting solution was distilled to obtain the title compound at 45% yield.

The obtained compound was subjected to IR absorption spectrometry to find that absorption attributed to SiC was observed at 1060 cm⁻¹ and accordingly the compound had an SiC bond.

Further, when a solution containing the compound was subjected to ultraviolet to visible absorption spectrometry, absorption at wavelength of 390 nm was observed. Further, the compound was subjected to nuclear magnetic resonance (NMR) measurement. Since the compound has high reactivity, it was impossible to carry out direct NMR measurement of the compound and therefore the compound was reacted with ethanol (generation of hydrogen chloride was confirmed) to replace chlorine at the terminal with an ethoxy group and then the measurement was carried out.

7.30 ppm (m) (1H derived from thiophene ring)

7.20 ppm to 7.00 ppm (m) (8H derived from thiophene ring)

2.20 ppm (m) (3H derived from ethoxy group)

Based on these results, the compound was confirmed to be quaterthiophenetrichlorosilane.

### Synthesis Example 15

### Synthesis of 2-methylsexi-thiophenetrimethoxysilane

First, bromoterthiophene was produced in the same manner as Synthesis Example 1.

Successively, methylterthiophene was synthesized by reaction of 1.0 mole of the above-mentioned bromoterthiphene and 1.0 mole of bromomethane at 60° C. for 3 hours. Next, 0.7 mole of the above-mentioned methylterthiphene was reacted with NBS in the presence of AIBN to synthesize 2-methyl-5″-bromoterthiophene.

On the other hand, 0.5 mole of metal magnesium and 300 ml of THF (tetrahydrofuran) were loaded to a 500 ml glass flask equipped with a stirrer, a refluxing condenser, a thermometer, and a titration funnel and 0.5 mole of the above-mentioned bromoterthiophene was dropwise added through the titration funnel at 50 to 60° C. over 2 hours and on completion of the titration, aging was carried out at 65° C. for 2 hours to synthesize Grignard reagent.

Successively, the above-mentioned 2-methyl-5″-bromoterthiophene was added and reaction was carried out at 60° C. for 4 hours to synthesize 2-methylsexi-thiophene. Further, after 0.2 mole of the above-mentioned 2-methylsexi-thiophene was reacted with NBS in the presence of AIBN to synthesize 2-methyl-5″″″-bromosexi-thiophene, reaction with metal magnesium was carried out to obtain Grignard reagent. Further, a 1 l glass flask equipped with a stirrer, a refluxing condenser, a thermometer, and a titration funnel was loaded with 1.5 mole of trimethoxychlorosilane and 300 ml of toluene and cooled with ice and the above-mentioned Grignard reagent was dropwise added over 2 hours at an inner temperature of 20° C. or lower and on completion of titration, aging was carried out at 30° C. for 1 hour.

Next, after the reaction solution was filtered under reduced pressure to remove magnesium chloride, toluene and unreacted substances were stripped from the obtained filtrate and the resulting solution was distilled to obtain the title compound.

The obtained compound was subjected to IR absorption spectrometry to find that absorption attributed to SiC was observed at 1050 cm⁻¹ and accordingly the compound had an SiC bond.

Further, the compound was subjected to nuclear magnetic resonance (NMR) measurement.

7.3 ppm (m) (2H derived from thiophene ring)

7.1 ppm (m) (10H derived from thiophene ring)

3.8 ppm (m) (6H derived from methylene of ethoxy group)

2.6 ppm (m) (3H derived from methyl group)

1.2 ppm (m) (9H derived from methyl group of ethoxy group)

Based on these results, the compound was confirmed to be the title compound.

### Synthesis Example 16

### Synthesis of 2-methylheptathiophenetrimethoxysilane

First, bromoterthiophene and bromoquaterthiophene as intermediates were produced in the same manner as Synthesis Examples 1 and 2.

Successively, methylquaterthiophene was synthesized by reaction of 1.0 mole of bromoquaterthiphene and 1.0 mole of bromomethane at 60° C. for 3 hours. Next, 0.7 mole of the above-mentioned methylquaterthiphene was reacted with NBS in the presence of AIBN to synthesize 2-methyl-5″-bromoquaterthiophene.

On the other hand, 0.5 mole of metal magnesium and 300 ml of THF (tetrahydrofuran) were loaded to a 500 ml glass flask equipped with a stirrer, a refluxing condenser, a thermometer, and a titration funnel and 0.5 mole of the above-mentioned bromoterthiophene was dropwise added through the titration funnel at 50 to 60° C. over 2 hours and on completion of the titration, aging was carried out at 65° C. for 2 hours to synthesize Grignard reagent.

Successively, the above-mentioned 2-methyl-5″″-bromoquaterthiophene was further added and reaction was carried out at 60° C. for 4 hours to synthesize 2-methylheptathiophene. Further, after 0.2 mole of the above-mentioned 2-methylheptathiophene was reacted with NBS in the presence of AIBN to synthesize 2-methyl-5″″″′-bromoheptathiophene, reaction with metal magnesium was carried out to obtain Grignard reagent. Further, a 1 l glass flask equipped with a stirrer, a refluxing condenser, a thermometer, and a titration funnel was loaded with 1.5 mole of trimethoxychlorosilane and 300 ml of toluene and cooled with ice and the above-mentioned Grignard reagent was dropwise added over 2 hours at an inner temperature of 20° C. or lower and on completion of titration, aging was carried out at 30° C. for 5 hours.

Next, after the reaction solution was filtered under reduced pressure to remove magnesium chloride, toluene and unreacted substances were stripped from the obtained filtrate and the resulting solution was distilled to obtain the title compound.

The obtained compound was subjected to IR absorption spectrometry to find that absorption attributed to SiC was observed at 1050 cm⁻¹ and accordingly the compound had an SiC bond.

Further, the compound was subjected to nuclear magnetic resonance (NMR) measurement.

7.3 ppm (m) (2H derived from thiophene ring)

7.1 ppm (m) (12H derived from thiophene ring)

3.8 ppm (m) (6H derived from methylene of ethoxy group)

2.6 ppm (m) (3H derived from methyl group)

1.2 ppm (m) (9H derived from methyl group of ethoxy group)

Based on these results, the compound was confirmed to be the title compound.

### Synthesis Example 17

### Synthesis of 2-methyloctathiophenetrimethoxysilane

First, bromoquaterthiophene was produced in the same manner as Synthesis Example 2 and 2-methyl-5″′-bromoquaterthiophene was produced in the same manner as Synthesis Example 16.

On the other hand, 0.5 mole of metal magnesium and 300 ml of THF (tetrahydrofuran) were loaded to a 500 ml glass flask equipped with a stirrer, a refluxing condenser, a thermometer, and a titration funnel and 0.5 mole of the above-mentioned bromoquaterthiophene was dropwise added through the titration funnel at 50 to 60° C. over 2 hours and on completion of the titration, aging was carried out at 65° C. for 2 hours to synthesize Grignard reagent.

Successively, the above-mentioned 2-methyl-5″″-bromoquaterthiophene was further added and reaction was carried out at 60° C. for 4 hours to synthesize 2-methyloctathiophene. Further, after 0.2 mole of the above-mentioned 2-methyloctathiophene was reacted with NBS in the presence of AIBN to synthesize 2-methyl-5″″″″-bromooctathiophene, reaction with metal magnesium was carried out to obtain Grignard reagent. Further, a 1 l glass flask equipped with a stirrer, a refluxing condenser, a thermometer, and a titration funnel was loaded with 1.5 mole of trimethoxychlorosilane and 300 ml of toluene and cooled with ice and the above-mentioned Grignard reagent was dropwise added over 2 hours at an inner temperature of 20° C. or lower and on completion of titration, aging was carried out at 30° C. for 5 hours.

Next, after the reaction solution was filtered under reduced pressure to remove magnesium chloride, toluene and unreacted substances were stripped from the obtained filtrate and the resulting solution was distilled to obtain the title compound.

The obtained compound was subjected to IR absorption spectrometry to find that absorption attributed to SiC was observed at 1050 cm⁻¹ and accordingly the compound had an SiC bond.

Further, the compound was subjected to nuclear magnetic resonance (NMR) measurement.

7.3 ppm (m) (2H derived from thiophene ring)

7.1 ppm (m) (12H derived from thiophene ring)

3.8 ppm (m) (6H derived from methylene of ethoxy group)

2.6 ppm (m) (3H derived from methyl group)

1.2 ppm (m) (9H derived from methyl group of ethoxy group)

Based on these results, the compound was confirmed to be the title compound.

### Synthesis Example 18

### Synthesis of anthracenetriethoxysilane

Anthracenetriethoxysilane was synthesized in the following manner.

First, 1 mM of anthracene dissolved in 50 mL of carbon tetrachloride and NBS were added to a 100 ml eggplant flask equipped with a stirrer, a refluxing condenser, a thermometer, and a titration funnel and in the presence of AIBN, reaction was carried out for 1.5 hours. After unreacted substances and HBr were removed by filtration, a stored compound brominated at one position was taken out by column chromatography to obtain 9-bromoanthracene. Successively, reaction with metal magnesium was carried out to obtain Grignard reagent and successively, Grignard reagent was dissolved in a carbon tetrachloride solution containing chlorotriethoxysilane and reacted at 60° C. for 2 hours to obtain the title compound (yield 15%).

The obtained compound was subjected to IR absorption spectrometry to find that absorption attributed to Si—O—C was observed at 1050 nm⁻¹ and accordingly the compound had a silyl group. Further, the compound was subjected to nuclear magnetic resonance (NMR) measurement.

7.80 ppm to 7.60 ppm (m) (9H derived from aromatic group)

3.8 ppm (m) (6H derived from methylene group of ethoxy group)

1.5 ppm (m) (9H derived from methyl group of ethoxy group)

Based on these results, the compound was confirmed to be the title compound.

### Synthesis Example 19

### Synthesis of naphthacenetriethoxysilane

Naphthacenetriethoxysilane was synthesized in the following manner. First, 1 mM of naphthacene dissolved in 50 mL of carbon tetrachloride and NBS were added to a 100 ml eggplant flask equipped with a stirrer, a refluxing condenser, a thermometer, and a titration funnel and in the presence of AIBN, reaction was carried out for 1.5 hours. After unreacted substances and HBr were removed by filtration, a stored compound brominated at one position was taken out by column chromatography to obtain 9-bromonaphthacene. Successively, reaction with metal magnesium was carried out to obtain Grignard reagent and successively, Grignard reagent was dissolved in a chloroform solution containing H—Si(OC₂H₅)₃ and reacted at 60° C. for 2 hours to obtain the title compound (yield 10%).

The obtained compound was subjected to IR absorption spectrometry to find that absorption attributed to Si—O—C was observed at 1050 nm⁻¹ and accordingly the compound had a silyl group. Further, when a chloroform solution containing the compound was subjected to ultraviolet to visible absorption spectrometry, absorption at wavelength of 481 nm was observed. The absorption is attributed to π→π* transition of the naphthacene skeleton contained in the molecule to prove that the compound contained a naphthacene skeleton.

Further, the compound was subjected to nuclear magnetic resonance (NMR) measurement.

7.80 ppm to 7.30 ppm (m) (11H derived from aromatic group)

3.6 ppm (m) (6H derived from methylene group of ethoxy group)

1.4 ppm (m) (9H derived from methyl group of ethoxy group)

Based on these results, the compound was confirmed to be the title compound.

### Synthesis Example 20

### Synthesis of hexacenetriethoxysilane

### (1) Synthesis of 2,3,6,7-tetra(trimethylsilyl)naphthalene

First, 0.4 M of magnesium, 100 ml of HMPT (hexamethyl phosphorous triamide), 20 ml of THF, I₂ (catalyst), and 0.1 M of 1,2,4,5-tetrachlorobenzene (99% purity, commercialized by Kishida Chemical Co., Ltd., for example) were added to a 200 ml glass flask equipped with a stirrer, a refluxing condenser, a thermometer, and a titration funnel and 0.4 M of chlorotrimethylsilane was dropwise added at 80° C. and after stirring for 30 minutes, the mixture was refluxed at 130° C. for 4 days to synthesize 1,2,4,5-tetra(trimethylsilyl)benzene.

Successively, after 20 mM of i-Pr₂NH, 50 mM of PhI(OAc)₂ ((diacetoxyiodo)benzene), and 50 ml of dichloromethane were added to a 200 mL eggplant flask, 50 mM of CF₃CO₂H(T_{f}OH) was dropwise added at 0° C. and stirred for 2 hours. Successively, 10 mL of a dichloromethane solution containing 50 mM of the above-mentioned 1,2,4,5-tetra(trimethylsilyl)benzene was dropwise added at 0° C. and stirred at a room temperature for 2 hours to synthesize phenyl[2,4,5-tris(trimethylsilyl)phenyl]iodonium triflate.

Successively, a THF solution containing 2.0 M of Bu₄NF was loaded to a 50 ml eggplant flask and 5 mM of the above-mentioned phenyl[2,4,5-tris(trimethylsilyl)phenyl]iodonium triflate and 10 ml of a dichloromethane solution containing 10 mM of 3,4-di(trimethylsilyl)furan were dropwise added at 0° C. and stirred for 30 minutes to promote the reaction. On completion of the reaction, the obtained product was extracted with dichloromethane and water and purified by column chromatography to obtain a 1,4-dihydro-1,4-epoxynaphthalene derivative.

After that, 10 mL of a THF solution containing 1 mM of lithium iodide, the above-mentioned 1,4-dihydro-1,4-epoxynaphthalene derivative and 10 mM of DBU were loaded to a 50 ml glass flask equipped with a stirrer, a refluxing condenser, a thermometer, and a titration funnel, and after 1 mM of the above-mentioned 1,4-dihydro-1,4-epoxynaphthalene derivative was added, the mixture was refluxed for 3 hours in nitrogen atmosphere to promote the reaction. On completion of the reaction, water was removed by extraction and MgSO₄ to synthesize the title compound, 2,3,6,7-tetra(trimethylsilyl)naphthalene.

### (2) Synthesis of hexacene

First, 2,3,6,7-tetra(trimethylsilyl)naphthalene was used as a starting raw material and synthesis was carried out in the same manner as that for synthesizing 2,3,6,7-tetra(trimethylsilyl)naphthalene from 1,2,4,5-tetra(trimethylsilyl)benzene in Preparation Example (1) and the process was repeated 4 times to synthesize 2,3,10,11-tetra(trimethylsilyl)-hexacene.

Successively, after 1 mM of the above-mentioned 2,3,10,11-tetra(trimethylsilyl)-hexacene was dissolved in a THF solvent containing a small amount of water and PhNMe₃F, the mixture was stirred to synthesize 2,3,10,11-tetra(trimethylsilyl)-hexacene.

When the synthesized compound was subjected to nuclear magnetic resonance (NMR) measurement, the following spectrum was observed.

8.1 ppm 4H

7.9 ppm 8H

7.4 ppm 4H

Based on these results, the compound was confirmed to be the title compound.

### (3) Synthesis of hexacenetriethoxysilane

Hexacenetriethoxysilane was synthesized in the following manner. First, 1 mM of hexacene dissolved in 50 mL of carbon tetrachloride and NBS were added to a 100 ml eggplant flask equipped with a stirrer, a refluxing condenser, a thermometer, and a titration funnel and reaction was carried out for 1.5 hours in the presence of AIBN. After unreacted substances and HBr were removed by filtration, a stored compound brominated at one position was taken out by column chromatography to obtain 9-hexapentacene. Successively, reaction with metal magnesium was carried out to obtain Grignard reagent and successively, Grignard reagent was dissolved in a chloroform solution containing H—Si(OC₂H₅)₃ and reacted at 60° C. for 2 hours to obtain the title compound (yield 10%).

The obtained compound was subjected to IR absorption spectrometry to find that absorption attributed to Si—O—C was observed at 1060 nm⁻¹ and accordingly the compound had a silyl group.

Further, the compound was subjected to nuclear magnetic resonance (NMR) measurement.

7.80 ppm to 7.30 ppm (m) (15H derived from aromatic group)

3.6 ppm (m) (6H derived from methylene group of ethoxy group)

1.4 ppm (m) (9H derived from methyl group of ethoxy group)

Based on these results, the compound was confirmed to be the title compound.

While the invention has been described as mentioned above, various obvious modifications are similarly possible by various means. Such modifications do not deviate from the purpose and scope of the invention, and all the modifications obvious to those skilled in the art are within the scope of the invention as defined by the appended claims.

This application is related to Japanese Unexamined Patent Application Nos. 2004-371789 filed on Dec. 22, 2004 and 2005-346654 filed on Nov. 30, 2005, and the disclosures of which are incorporated by reference in their entirety.

1. An organic TFT comprising an organic thin film, a gate electrode formed on one surface of the organic thin film through a gate insulating film, source/drain electrodes formed on both sides of the gate electrode and on one surface of the organic thin film or on the other surface, and a film of an organic silane compound positioned between the organic thin film and the gate insulating film and/or between the organic thin film and the source/drain electrodes.

2. The organic TFT according to claim 1, wherein the organic silane compound between the gate insulating film and the organic thin film is an anchor film, the anchor film is a monomolecular film having a carrier transportation function.

3. The organic TFT according to claim 2, wherein the anchor film has crystalline.

4. The organic TFT according to claim 2, wherein the thickness of the anchor film is 0.5 nm to 3 nm.

5. The organic TFT according to claim 1, wherein the organic silane compound between the organic thin film and the source/drain electrodes is a buffer film, the buffer film is a monomolecular film having an energy barrier.

6. The organic TFT according to claim 5, wherein the source/drain electrodes consist of a metal material on whose surface an oxide film can be formed.

7. The organic TFT according to claim 5, wherein the thickness of the buffer film is 0.5 nm to 5 nm.

8. The organic TFT according to claim 1, wherein the organic silane compound contains a π electron conjugated system molecules.

9. The organic TFT according to claim 1, wherein the organic silane compound defines by the following formula (1);
R¹—SiZ¹Z²Z³ (1)
wherein R¹ is a monovalent group containing π electron conjugated system molecules, the n electron conjugated system molecules are molecules consisting of 2 to 6 repeated benzene, molecules consisting of 2 to 6 repeated thiophene, acene molecules consisting of 2 to 6 condensed benzene rings, or molecules obtained by combining them; Z¹ to Z³ are same or different and denote a halogen atom or an alkoxy atom having 1 to 5 carbon atoms.

10. The organic TFT according to claim 1, wherein the organic silane compound defines by the following formula (1);
R¹—SiZ¹Z²Z³ (1)
wherein R¹ is a monovalent group containing π electron conjugated system molecules, the π electron conjugated system molecules are molecules consisting of 2 to 6 repeated thiophene; Z¹ to Z³ are same or different and denote a halogen atom or an alkoxy atom having 1 to 5 carbon atoms.

11. The organic TFT according to claim 1, wherein the organic silane compound defines by the following formula (1);
R¹—SiZ¹Z²Z³ (1)
wherein R¹ is a monovalent group containing π electron conjugated system molecules, the n electron conjugated system molecules are acene molecules consisting of 2 to 6 condensed benzene rings; Z¹ to Z³ are same or different and denote a halogen atom or an alkoxy atom having 1 to 5 carbon atoms.

12. The organic TFT according to claim 1, wherein the organic silane compound defines by the following formula (1);
R¹—SiZ¹Z²Z³ (1)
wherein R¹ is a monovalent group containing π electron conjugated system molecules, the π electron conjugated system molecules contain at least two or more molecules selected from molecules consisting of 2 to 6 repeated benzene, molecules consisting of 2 to 6 repeated thiophene, and acene molecules consisting of 2 to 6 condensed benzene rings; Z¹ to Z³ are same or different and denote a halogen atom or an alkoxy atom having 1 to 5 carbon atoms.

13. The organic TFT according to claim 1, wherein the organic thin film is a film formed by using a low molecular weight compound or polymer compound.

14. A fabrication method of the organic TFT of claim 1 comprising a step of forming a film of an organic silane compound between the organic thin film and the gate insulating film and/or between the organic thin film and the source/drain electrodes.

15. A fabrication method of the organic TFT according to claim 14, wherein the film of the organic silane compound provides between the organic thin film and gate insulating film, and is an anchor film which is a monomolecular film having a carrier transportation function;
the method comprises steps of:
forming the gate insulating film on the gate electrode,
forming the anchor film on the gate insulating film,
forming the organic thin film on the anchor film, and
forming source/drain electrodes on the anchor film before formation of the organic thin film or forming the source/drain electrodes on the organic thin film

16. A fabrication method of the organic TFT according to claim 14, wherein the film of the organic silane compound provides between the organic thin film and source/drain electrodes, and is a buffer film which is a monomolecular film having a energy barrier;
the method comprises step of:
forming the source/drain electrodes on the buffer film after the buffer film covers a contact surface of which the organic thin film contacts with the source/drain electrodes, or
forming the organic thin film on the buffer film after the buffer film covers a contact surface of which the source/drain electrodes contacts with the organic thin film.

17. A fabrication method of the organic TFT according to claim 14, wherein the film of the organic silane compound is formed by a dipping or LB method.

18. A fabrication method of the organic TFT according to claim 14, wherein the organic thin film is formed by a solution coating method.
